(19) United States
(12) Patent Application Publication
(10) Pub. No.: US 2026/0107613 A1
(43) Pub. Date: Apr. 16, 2026

(54) DISPLAY PANEL AND ELECTRONIC DEVICE COMPRISING THE SAME

(71) Applicant: Samsung Display Co., Ltd., Yongin-si (KR)

(72) Inventors: Junsu Park, Yongin-si (KR); Junhyeong Park, Yongin-si (KR)

(21) Appl. No.: 19/354,489

(22) Filed: Oct. 9, 2025

(30) Foreign Application Priority Data
Oct. 15, 2024 (KR) 10-2024-0140548

(51) Int. Cl. H10H 29/49; H10H 29/41

(52) U.S. Cl. CPC H10H 29/49; H10H 29/41

(57) ABSTRACT

A display panel includes a base layer, first and second pixel circuit layers spaced from each other on the base layer and each including a transistor and insulating layers, a first light-emitting diode on the first pixel circuit layer and electrically connected to the transistor of the first pixel circuit layer, a second light-emitting diode on the second pixel circuit layer and electrically connected to the transistor of the second pixel circuit layer, a first line electrically connected to the transistor of the first pixel circuit layer, a second line electrically connected to the transistor of the second pixel circuit layer, and a connection line electrically connecting the first line to the second line, wherein the a first portion of the first line extends toward the connection line, and at least a portion of the first portion is embedded within the connection line.

### CROSS-REFERENCE TO RELATED APPLICATION

This application claims priority to and the benefit of Korean Patent Application No. 10-2024-0140548, filed on Oct. 15, 2024, in the Korean Intellectual Property Office, the entire disclosure of which is incorporated by reference herein.

### BACKGROUND

### 1. Field

One or more embodiments relate to a display panel. One or more embodiments relate to a display panel, a process of manufacturing the display panel, and an electronic apparatus including the display panel.

### 2. Description of the Related Art

With the development of display panels that visually display different types of electrical signals, various display panels having excellent characteristics such as thinness, light weight, low power consumption, and the like, and electronic apparatuses including such display panels have been developed. For example, research and development of display panels having various structures, such as flexible display panels that are foldable, rollable in a roll shape, and stretchable display panels, and electronic apparatuses including such display panels have been actively carried out.

### SUMMARY

One or more embodiments include a display panel, for example, a flexible display panel, an electronic apparatus including the flexible display panel, and a process of manufacturing the display panel.

Additional aspects will be set forth in part in the description which follows and, in part, will be apparent from the description, or may be learned by practice of the presented embodiments of the present disclosure.

According to one or more embodiments, a display panel includes a base layer including a first surface and a second surface opposite the first surface, a first pixel circuit layer on the first surface of the base layer and including a transistor and insulating layers, a second pixel circuit layer on the first surface of the base layer, spaced from the first pixel circuit layer, and including transistors and insulating layers, a first light-emitting diode on the first pixel circuit layer and electrically connected to the transistor of the first pixel circuit layer, a second light-emitting diode on the second pixel circuit layer and electrically connected to the transistor of the second pixel circuit layer, a first line electrically connected to the transistor of the first pixel circuit layer, a second line electrically connected to the transistor of the second pixel circuit layer, and a connection line electrically connecting the first line to the second line, wherein a first portion of the first line extends toward the connection line, and at least a portion of the first portion is embedded within the connection line.

A bottom surface and a lateral surface of the first portion of the first line may be in direct contact with the connection line.

The insulating layers of each of the first pixel circuit layer and the second pixel circuit layer may include an inorganic insulating stack including inorganic insulating layers, and a first organic insulating layer on the inorganic insulating stack, wherein the first organic insulating layer of the first pixel circuit layer may overlap the first portion of the first line.

The first organic insulating layer may be in direct contact with an upper surface of the first portion of the first line.

A portion of the base layer may be in direct contact with a portion of a lateral surface of the inorganic insulating stack.

The connection line may include a first portion overlapping the first organic insulating layer and not overlapping the first portion of the first line, and a second portion located between the first organic insulating layer of the first pixel circuit layer and the first organic insulating layer of the second pixel circuit layer, and a first thickness of the first portion of the connection line may be greater than a second thickness of the second portion of the connection line.

The connection line may further include a third portion overlapping the first portion of the first line, and a third thickness of the third portion of the connection line may be less than the first thickness.

The insulating layers of each of the first pixel circuit layer and the second pixel circuit layer may further include a second organic insulating layer on the first organic insulating layer, and a third organic insulating layer located between the inorganic insulating stack and the first organic insulating layer and overlapping a lateral surface of the inorganic insulating stack, and wherein a portion of the first line may be between the third organic insulating layer and the first organic insulating layer.

A width of the first organic insulating layer may be greater than a width of the inorganic insulating stack.

The first line may include a first layer including a first metal, and a second layer including a metal different from the first layer and located on the first layer, wherein the second layer may include a tip protruding in a lateral direction from a point at which a lateral surface of the first layer meets a bottom surface of the second layer, and the connection line may be in direct contact with a lateral surface and a bottom surface of the tip.

The display panel may further include a protective layer on the first light-emitting diode and the second light-emitting diode, wherein the protective layer may be in direct contact with the connection line.

According to one or more embodiments, a display panel includes a base layer including two first regions spaced from each other, and a second region between the two first regions, a first pixel circuit layer in one of the two first regions of the base layer and including a transistor and insulating layers, a second pixel circuit layer in an other one of the two first regions of the base layer, spaced from the first pixel circuit layer, and including transistors and insulating layers, a first light-emitting diode on the first pixel circuit layer and electrically connected to the transistor of the first pixel circuit layer, a second light-emitting diode on the second pixel circuit layer and electrically connected to the transistor of the second pixel circuit layer, a first line electrically connected to the transistor of the first pixel circuit layer, a second line electrically connected to the transistor of the second pixel circuit layer, and a connection line electrically connecting the first line to the second line, wherein the first line extends toward the connection line, and a bottom surface and a lateral surface of a first portion of the first line are in direct contact with the connection line.

The insulating layers of each of the first pixel circuit layer and the second pixel circuit layer may include an inorganic insulating stack including inorganic insulating layers, and a first organic insulating layer on the inorganic insulating stack, and wherein the first organic insulating layer may overlap the first portion of the first line.

The connection line may include a first portion overlapping the first organic insulating layer and not overlapping the first portion of the first line, and a second portion located in the second region, and wherein a first thickness of the first portion of the connection line may be greater than a second thickness of the second portion of the connection line.

The connection line may further include a third portion overlapping the first portion of the first line, and a third thickness of the third portion of the connection line may be less than the first thickness.

The insulating layers of each of the first pixel circuit layer and the second pixel circuit layer may further include a second organic insulating layer between the inorganic insulating stack and the first organic insulating layer and overlapping a lateral surface of the inorganic insulating stack, wherein a portion of the first line may be between the second organic insulating layer and the first organic insulating layer.

A portion of the base layer may be in direct contact with a portion of a lateral surface of the inorganic insulating stack.

The first organic insulating layer may be in direct contact with an upper surface of the first portion of the first line.

The first line may include a first layer including a first metal, a second layer including a metal different from the first layer and on the first layer, wherein the second layer may include a tip protruding in a lateral direction from a point at which a lateral surface of the first layer meets a bottom surface of the second layer, and the connection line may be in direct contact with a lateral surface and a bottom surface of the tip.

The display panel may further include a protective layer on the first light-emitting diode and the second light-emitting diode, wherein the protective layer may be in direct contact with the connection line.

An electronic device including a display panel, the display panel includes: a base layer including a first surface and a second surface opposite the first surface; a first pixel circuit layer on the first surface of the base layer and comprising a transistor and insulating layers; a second pixel circuit layer on the first surface of the base layer, spaced from the first pixel circuit layer, and comprising transistors and insulating layers; a first light-emitting diode on the first pixel circuit layer and electrically connected to the transistor of the first pixel circuit layer; a second light-emitting diode on the second pixel circuit layer and electrically connected to the transistor of the second pixel circuit layer; a first line electrically connected to the transistor of the first pixel circuit layer; a second line electrically connected to the transistor of the second pixel circuit layer; and a connection line electrically connecting the first line to the second line, wherein a first portion of the first line extends toward the connection line, and at least a portion of the first portion is embedded within the connection line.

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic perspective view of a display panel according to one or more embodiments;

FIGS. 2A and 2B are perspective views of the display panel of FIG. 1 stretched in a first direction;

FIG. 2C is a perspective view of the display panel of FIG. 1 stretched in a second direction;

FIG. 2D is a perspective view of the display panel of FIG. 1 stretched in the first direction and the second direction;

FIG. 2E is a perspective view of the display panel of FIG. 1 stretched in a third direction;

FIG. 3 is a schematic excerpted plan view of a display area of a display panel according to one or more embodiments;

FIG. 4 is an excerpted cross-sectional view of a first region of FIG. 3;

FIG. 5A-5C are equivalent circuit diagrams of a pixel of a display panel according to one or more embodiments;

FIG. 6A-6E are schematic cross-sectional views of a light-emitting diode of a display panel according to one or more embodiments;

FIG. 7 is a schematic plan view of a portion of the display area of a display panel according to one or more embodiments;

FIG. 8 is a schematic plan view of a portion of the display area of a display panel according to one or more embodiments;

FIG. 9 is an excerpted plan view of a portion of a display panel according to one or more embodiments;

FIG. 10 is a cross-sectional view of the display panel taken along the line X-X′ of FIG. 9;

FIG. 11A is an excerpted enlarged cross-sectional view of a region XIA of FIG. 10;

FIG. 11B is a schematic perspective view of FIG. 11A;

FIGS. 12A and 12B are cross-sectional views of the display panel taken along the line XII-XII′ of FIG. 9;

FIG. 13 is a cross-sectional view of a portion of the display panel taken along the line X-X′ of FIG. 9, according to one or more embodiments;

FIG. 14A-14H are cross-sectional views showing processes of a method of manufacturing a display panel according to one or more embodiments;

FIG. 15 is a schematic perspective view of an electronic apparatus including a display panel according to one or more embodiments;

FIG. 16 is a block diagram of an electronic apparatus including a display panel according to one or more embodiments; and

FIGS. 17 and 18 are perspective views of an electronic apparatus according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the present disclosure, the expression “at least one of a, b and c” indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects, aspects, and features of the present disclosure, and methods for achieving them will be clarified with reference to embodiments described below in detail with reference to the drawings. However, the present disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the present disclosure is not necessarily limited thereto.

In the case where a certain embodiment may be implemented differently, a specific process order may be performed in the order different from the described order. As an example, two processes successively described may be concurrently (e.g., simultaneously) performed substantially and performed in the opposite order.

It will be understood that when a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that when a layer, region, or element is referred to as being “electrically connected” to another layer, region, or element, it may be “directly electrically connected” to the other layer, region, or element or may be “indirectly electrically connected” to the other layer, region, or element with another layer, region, or element disposed therebetween.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

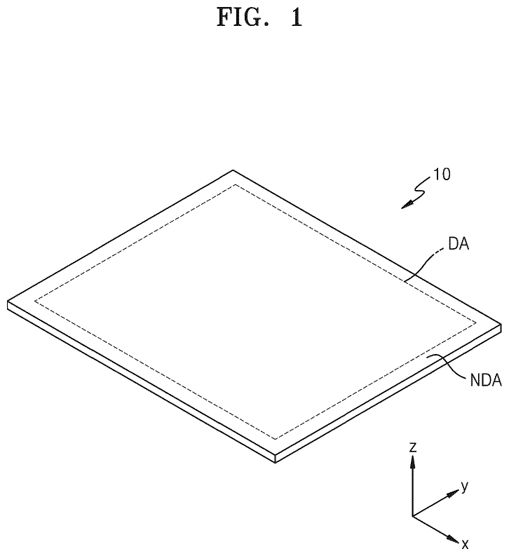

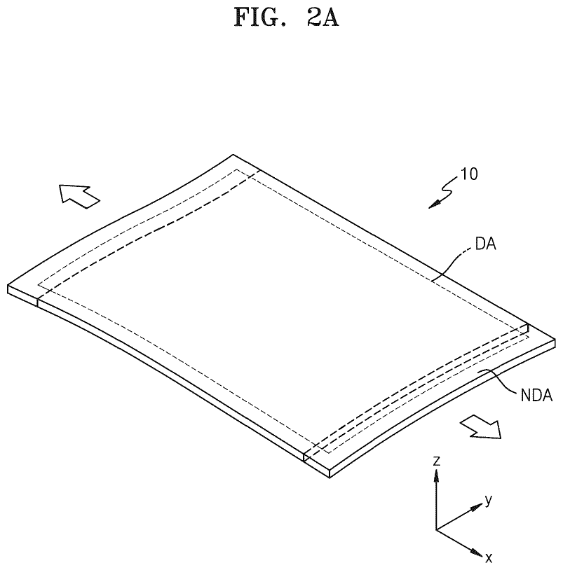

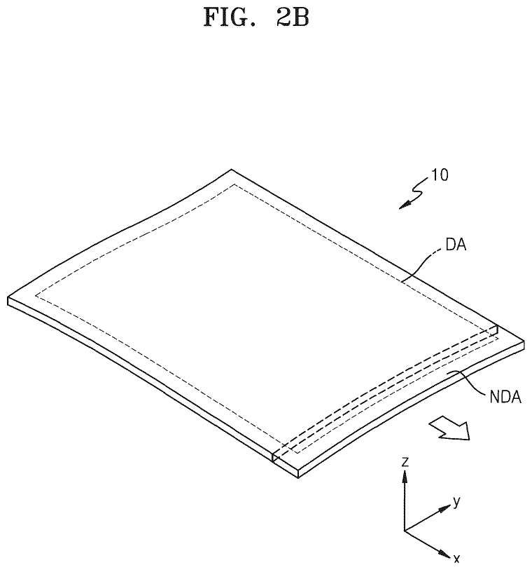

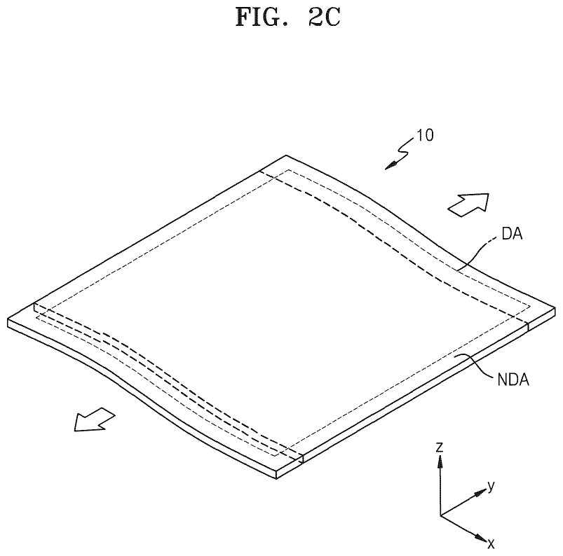

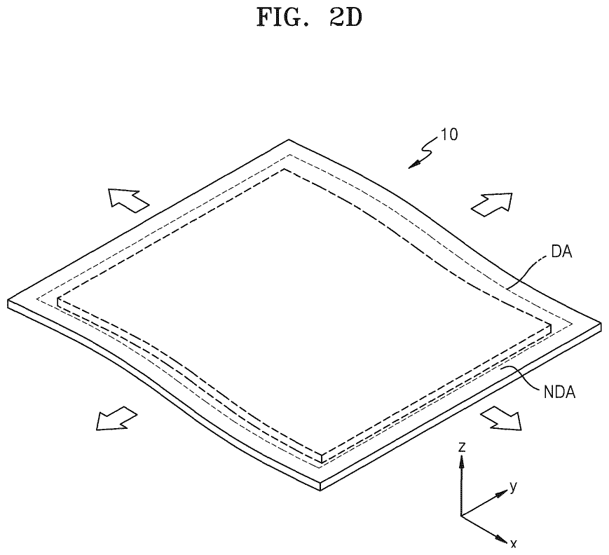

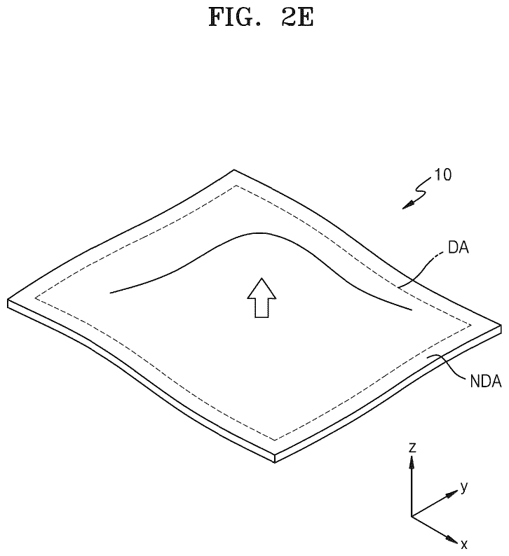

FIG. 1 is a schematic perspective view of a display panel 10 according to one or more embodiments. FIGS. 2A and 2B are perspective views of the display panel 10 of FIG. 1 stretched in a first direction. FIG. 2C is a perspective view of the display panel 10 of FIG. 1 stretched in a second direction. FIG. 2D is a perspective view of the display panel 10 of FIG. 1 stretched in the first direction and the second direction. FIG. 2E is a perspective view of the display panel 10 of FIG. 1 stretched in a third direction.

Referring to FIG. 1, the display panel 10 may include a display area DA and a non-display area NDA. The display area DA may include a plurality of pixels. The display panel 10 may be configured to display images by using light emitted from the plurality of pixels. The non-display area NDA may be outside the display area DA around an edge or a periphery of the display area DA. The non-display area NDA may surround the display area DA entirely.

The display panel 10 may be stretched or contracted in various directions. The display panel 10 may be stretched in the first direction (e.g., x direction and/or −x direction) by an external force exerted by an external object or a user. In one or more embodiments, as shown in FIGS. 2A and 2B, the display area DA and/or the non-display area NDA of the display panel 10 may be stretched in the first direction (e.g., x direction and/or −x direction). As an example, as shown in FIG. 2A, the display area DA and/or the non-display area NDA may be stretched in the x direction and −x direction, or as shown in FIG. 2B, may be stretched in the x direction with one side of the display panel 10 fixed.

The display panel 10 may be stretched in the second direction (e.g., y direction and/or −y direction) by an external force exerted by an external object or a user. In one or more embodiments, as shown in FIG. 2C, the display area DA and/or the non-display area NDA of the display panel 10 may be stretched in the y direction and -y direction. In another embodiment, the display panel 10 may be stretched in the y direction or −y direction with one side of the display panel 10 fixed.

The display panel 10 may be stretched in a plurality of directions, for example, the first direction (e.g., x direction and/or −x direction) and the second direction (e.g., y direction and/or −y direction) by an external force exerted by an external object or a portion of a person's body. As shown in FIG. 2D, the display area DA and/or the non-display area NDA of the display panel 10 may be stretched in a ±x direction and ±y direction.

The display panel 10 may be stretched in a third direction (e.g., z direction and/or −z direction) by an external force exerted by an external object or a portion of a person's body. In one or more embodiments, FIG. 2E shows a portion of the display panel 10, for example, a partial region of the display area DA that protrudes in the z direction. In another embodiment, a portion of the display panel 10, for example, a partial region of the display area DA, may protrude in the z direction (or may be recessed in the-z direction).

Although it is shown in FIG. 2A-2E that the display panel 10 is stretched in the first direction (e.g., the ±x direction), the second direction (e.g., the ±y direction), and/or the third direction (e.g., the ±z direction), the present disclosure is not limited thereto. In another embodiment, the display panel 10 may be variously transformed into an irregular shape by being bent and/or twisted along two or more axes.

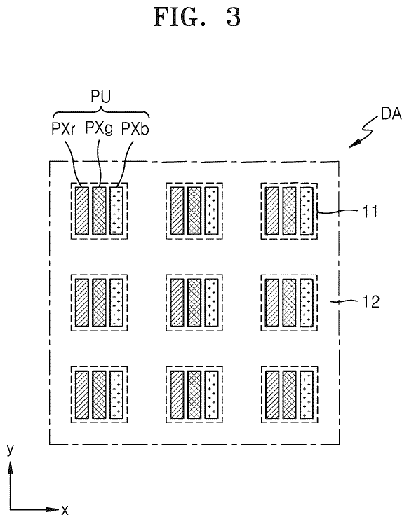

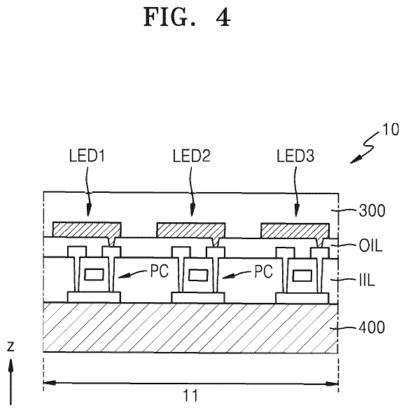

FIG. 3 is a schematic excerpted plan view of the display area DA of the display panel 10 according to one or more embodiments, and FIG. 4 is an excerpted cross-sectional view of the first region of FIG. 3.

Referring to FIG. 3, the display area DA may include first regions 11, and a second region 12 surrounding each of the first regions 11. The first regions 11 may be repeatedly arranged along the first direction (e.g., x direction) and the second direction (e.g., y direction).

The display area DA may include the first region 11 and the second region 12 having different elongations. As an example, the display panel 10 may include the first region 11 with a relatively small elongation, and the second region 12 with a relatively large elongation. In the present specification, an elongation is a numerical value representing a change ΔL/L in length by which the display panel 10 may be stretched without a physical damage to the display panel 10 when external force is applied to the display panel 10. Here, ΔL is an amount of change in length of the display panel 10, and L represents an initial length of the display panel 10. Accordingly, elongations of the first region 11 and the second region 12 may respectively represent changes in length of the first region 11 and the second region 12 when the same external force is applied to the first region 11 and the second region 12.

When an elongation of the first region 11 is less than an elongation of the second region 12, it may present that transformation of the first region 11 occurs relatively little due to external force. Accordingly, the first region 11 may be referred to as a low transformation region, and the second region 12 may be referred to as a high transformation region.

The first regions 11 may be spaced (e.g., spaced apart) from each other and arranged two-dimensionally in the display area DA. The first regions 11 may be regions in which pixels are disposed, and may be referred to as a pixel area or an emission area. One or more pixels may be disposed in each of the first regions 11. A pixel unit PU provided as a set of the pixels may be provided in the first region 11, and each pixel unit PU may include a red pixel PXr, a green pixel PXg, and a blue pixel PXb.

The red pixel PXr, the green pixel PXg, and the blue pixel PXb may respectively include a first light-emitting diode LED1, a second light-emitting diode LED2, and a third light-emitting diode LED3. Referring to FIG. 4, the first region 11 of the display panel 10 may include a pixel circuit PC, an inorganic insulating stack IIL, and an organic insulating layer OIL disposed on a base layer 400, the first to third light-emitting diodes LED1, LED2, and LED3 electrically connected to the pixel circuits PC, and a protective layer 300. An elongation of the first region 11 may be relatively less than an elongation of the second region 12 due to the stack structure of the pixel circuits PC, the inorganic insulating stack IIL, the organic insulating layer OIL, and the first to third light-emitting diodes LED1, LED2, and LED3 disposed in the first region 11.

The second region 12 may be located between the adjacent first regions 11. As shown in FIG. 3, in a plan view, the second region 12 may have a shape surrounding each of the first regions 11. The second region 12 may be a region across which a connection line for electrically connecting the pixel circuits PC (see FIG. 4) respectively disposed in the first regions 11 passes.

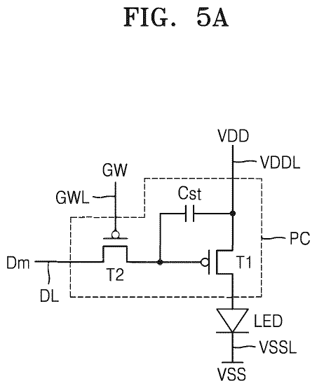

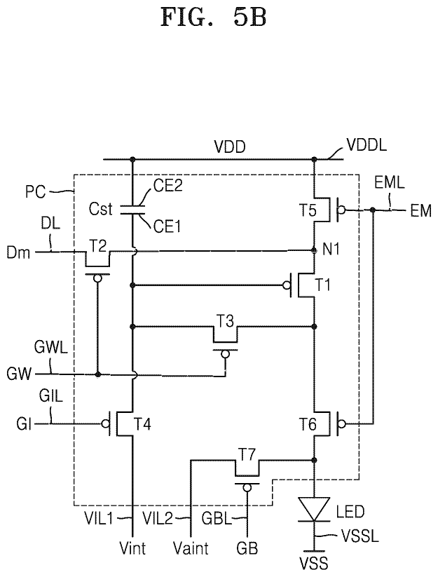

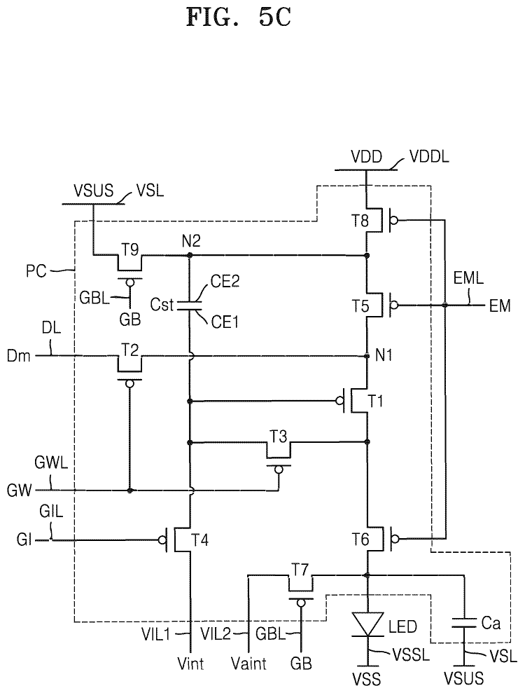

FIG. 5A-5C are equivalent circuit diagrams of a pixel of the display panel 10 according to one or more embodiments.

Referring to FIG. 5A, a light-emitting diode LED corresponding to a pixel may be electrically connected to the pixel circuit PC, and the pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL and a second voltage line VSSL.

The second transistor T2 may be electrically connected to the scan signal line GWL and the data line DL. The scan signal line GWL may provide a scan signal GW to a gate electrode of the second transistor T2. The second transistor T2 is configured to transfer a data signal Dm to the first transistor T1 according to a scan signal GW input from the scan signal line GWL, wherein the data signal Dm is input from the data line DL.

The storage capacitor Cst may be electrically connected to the second transistor T2 and the first voltage line VDDL and may store a voltage corresponding to a difference between a voltage transferred from the second transistor T2 and a first power voltage VDD supplied by the first voltage line VDDL.

The first transistor T1 is a driving transistor and may control a driving current flowing through the light-emitting element LED. The first transistor T1 may be connected between the first voltage line VDDL and the light-emitting element LED. The first transistor T1 may control the driving current flowing from the first voltage line VDDL to the light-emitting diode LED in response to a voltage value stored in the storage capacitor Cst connected to a gate electrode of the first transistor T1. The light-emitting diode LED may be configured to emit light having a preset brightness corresponding to the driving current. A first electrode of the light-emitting diode LED may be electrically connected to the first transistor T1, and a second electrode may be electrically connected to the second voltage line VSSL supplying a second power voltage VSS.

Although it is shown in FIG. 5A that the pixel circuit PC includes two transistors and one storage capacitor, the pixel circuit PC may include three or more transistors.

Referring to FIG. 5B, the pixel circuit PC may include the first transistor T1, the second transistor T2, a third transistor T3, a fourth transistor T4, a fifth transistor T5, a sixth transistor T6, a seventh transistor T7, and the storage capacitor Cst.

The pixel circuit PC is electrically connected to signal lines and voltage lines. The signal lines may include a gate line such as a scan signal line GWL, a bypass control line GBL, an initialization control line GIL, and an emission control line EML, and a data line DL. The voltage lines may include first and second initialization voltage lines VIL1 and VIL2, the first voltage line VDDL, and the second voltage line VSSL.

The first voltage line VDDL may transfer the first power voltage VDD to the first transistor T1. The first initialization voltage line VIL1 may be configured to transfer a first initialization voltage Vint to the pixel circuit PC, wherein the first initialization voltage Vint initializes the first transistor T1. The second initialization voltage line VIL2 may be configured to transfer a second initialization voltage Vaint to the pixel circuit PC, wherein the second initialization voltage Vaint initializes the first electrode of the light-emitting diode LED.

The first transistor T1 may be electrically connected to the first voltage line VDDL through the fifth transistor T5 and electrically connected to the light-emitting diode LED through the sixth transistor T6. The first transistor T1 serves as a driving transistor, receives a data signal Dm at a first electrode of the first transistor connected to a first node N1, and supplies the driving current to the light-emitting diode LED according to a switching operation of the second transistor T2.

The second transistor T2 is a data-write transistor and is electrically connected to the scan signal line GWL and the data line DL. The second transistor T2 is electrically connected to the first voltage line VDDL through the fifth transistor T5. The second transistor T2 is turned on according to a scan signal GW transferred through the scan signal line GWL, and performs a switching operation of transferring a data signal Dm to a first node N1, the data signal Dm being transferred through the data line DL.

The third transistor T3 is electrically connected to the scan signal line GWL and electrically connected to the light-emitting diode LED through the sixth transistor T6. The third transistor T3 may be connected between a second electrode and a gate electrode of the first transistor T1. The third transistor T3 may be turned on according to a scan signal GW to diode-connect the first transistor T1, wherein the scan signal GW is transferred through the scan signal line GWL.

The fourth transistor T4 serves as a first initialization transistor and is electrically connected to the initialization control line GIL and the first initialization voltage line VIL1. The fourth transistor T4 may be turned on according to an initialization control signal GI to initialize a voltage of the gate electrode of the first transistor T1 by transferring the first initialization voltage Vint to the gate electrode of the first transistor T1, wherein the initialization control signal GI is transferred through the initialization control signal GIL. The initialization control signal GI may correspond to a scan signal of another pixel circuit disposed in a previous row of the relevant pixel circuit PC.

The fifth transistor T5 may be an operation control transistor, and the sixth transistor T6 may be an emission control transistor. The fifth transistor T5 and the sixth transistor T6 may be electrically connected to the emission control line EML, concurrently (e.g., simultaneously) turned on according to an emission control signal EM transferred through the emission control line EML, and may form a current path such that the driving current flows in a direction from the first voltage line VDDL to the light-emitting diode LED. The first electrode of the light-emitting diode LED may be electrically connected to the first transistor T1 through the sixth transistor T6, and the second electrode may be electrically connected to the second voltage line VSSL supplying the second power voltage VSS.

The seventh transistor T7 serves as a second initialization transistor and may be electrically connected to the bypass control line GBL, the second initialization voltage line VIL2, and the sixth transistor T6. The seventh transistor T7 is turned on according to a bypass control signal GB transferred through the bypass control line GBL, and is configured to transfer the second initialization voltage Vaint from the second initialization voltage line VIL2 to the first electrode of the light-emitting diode LED, thereby initializing the first electrode of the light-emitting diode LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 5C, the pixel circuit PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel circuit PC is electrically connected to signal lines and voltage lines. The signal lines may include a gate line such as the scan signal line GWL, the bypass control line GBL, the initialization control line GIL, and the emission control line EML, and the data line DL. The voltage lines may include the first and second initialization voltage lines VIL1 and VIL2, a sustain voltage line VSL, the first voltage line VDDL, and the second voltage line VSSL.

The first voltage line VDDL may transfer the first power voltage VDD to the first transistor T1. The first initialization voltage line VIL1 may be configured to transfer the first initialization voltage Vint to the pixel circuit PC, wherein the first initialization voltage Vint initializes the first transistor T1. The second initialization voltage line VIL2 may be configured to transfer the second initialization voltage Vaint to the pixel circuit PC, wherein the second initialization voltage Vaint initializes the first electrode of the light-emitting diode LED. The sustain voltage line VSL may provide a sustain voltage VSUS to a second node N2, for example, the second electrode CE2 of the storage capacitor Cst during an initialization period and a data-write period.

The first transistor T1 may be connected to the first voltage line VDDL through the fifth transistor T5 and the eighth transistor T8 and electrically connected to the light-emitting diode LED through the sixth transistor T6. The first transistor T1 serves as the driving transistor, may receive a data signal Dm, and supply the driving current to the light-emitting diode LED according to a switching operation of the second transistor T2.

The second transistor T2 is electrically connected to the scan signal line GWL and the data line DL and electrically connected to the first voltage line VDDL through the fifth transistor T5 and the eighth transistor T8. The second transistor T2 may be turned on according to a scan signal GW transferred through the scan signal line GWL and may perform a switching operation of transferring a data signal Dm to the first node N1, wherein the data signal Dm is transferred through the data line DL.

The third transistor T3 is electrically connected to the scan signal line GWL and electrically connected to the light-emitting diode LED through the sixth transistor T6. The third transistor T3 may be turned on according to a scan signal GW to compensate for a threshold voltage of the first transistor T1 by diode-connecting the first transistor T1, wherein the scan signal GW is transferred through the scan signal line GWL.

The fourth transistor T4 is electrically connected to the initialization control line GIL and the first initialization voltage line VIL1, turned on according to an initialization control signal GI transferred through the initialization control line GIL, and initializes a voltage of the gate electrode of the first transistor T1 by transferring the first initialization voltage Vint from the first initialization voltage line VIL1 to the gate electrode of the first transistor T1. The initialization control signal GI may correspond to a scan signal of another pixel circuit disposed in a previous row of the relevant pixel circuit PC.

The fifth transistor T5, the sixth transistor T6, and the eighth transistor T8 may be electrically connected to the emission control line EML, concurrently (e.g., simultaneously) turned on according to an emission control signal EM transferred through the emission control line EML, and may form a current path such that the driving current flows in a direction from the first voltage line VDDL to the light-emitting diode LED. The first electrode of the light-emitting diode LED may be electrically connected to the first transistor T1 through the sixth transistor T6, and the second electrode may be electrically connected to the second voltage line VSSL supplying the second power voltage VSS.

The seventh transistor T7 serves as a second initialization transistor and may be electrically connected to the bypass control line GBL, the second initialization voltage line VIL2, and the sixth transistor T6. The seventh transistor T7 is turned on according to a bypass control signal GB transferred through the bypass control line GBL, and is configured to transfer the second initialization voltage Vaint from the second initialization voltage line VIL2 to the first electrode of the light-emitting diode LED, thereby initializing the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 is turned on according to a bypass control signal GB transferred through the bypass control line GBL and may transfer the sustain voltage VSUS to the second node N2, for example, the second electrode CE2 of the storage capacitor Cst during the initialization period and the data-write period.

Each of the eighth transistor T8 and the ninth transistor T9 may be electrically connected to the second node N2, for example, the second electrode CE2 of the storage capacitor Cst. In one or more embodiments, during the initialization period and the data-write period, the eighth transistor T8 may be turned off and the ninth transistor T9 may be turned on. During an emission period, the eighth transistor T8 may be turned on and the ninth transistor T9 may be turned off.

The storage capacitor Cst includes the first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting diode LED. The auxiliary capacitor Ca may prevent a black brightness from rising when the sixth transistor T6 is turned off by storing and maintaining a voltage corresponding to a voltage difference between the first electrode of the light-emitting diode LED and the sustain voltage line VSL while the seventh transistor T7 and the ninth transistor T9 are turned on.

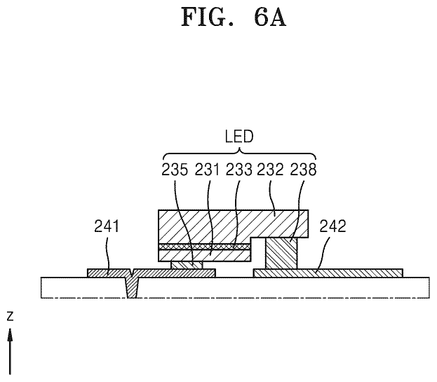

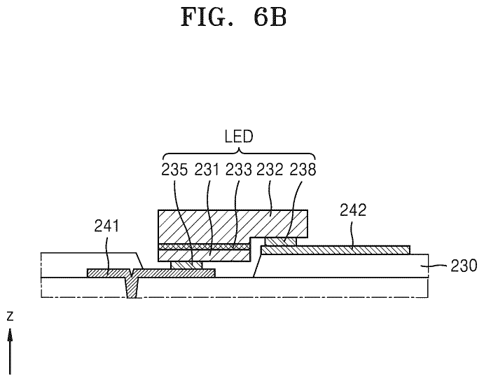

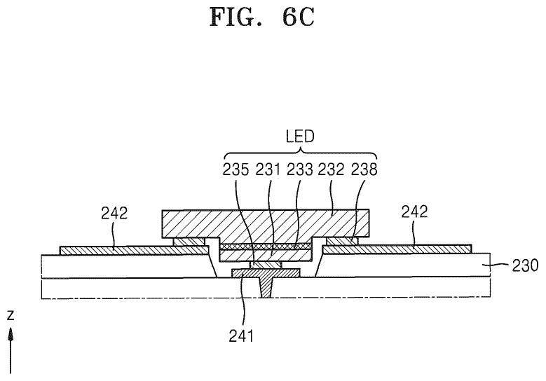

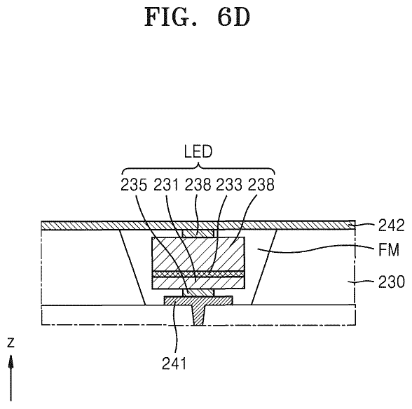

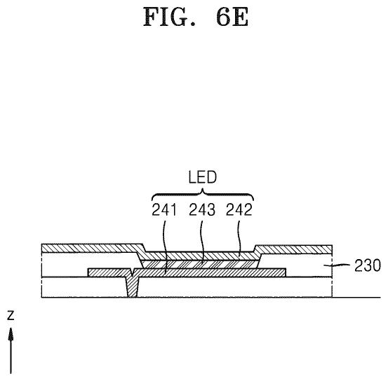

FIGS. 6A and 6E are schematic cross-sectional views of the light-emitting diode LED of the display panel 10 according to one or more embodiments.

Referring to FIG. 6A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be respectively electrically connected to a first electrode pad 241 and a second electrode pad 242 disposed on (or at) the same layer. The second electrode pad 242 may be a portion of the second voltage line VSSL (see FIG. 5A), or a conductive layer electrically connected to the second voltage line VSSL (see FIG. 5A).

In one or more embodiments, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and the like, and may be doped with a p-type dopant such as Mg, Zn, Ca, Sr, and/or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and the like, and may be doped with an n-type dopant such as Si, Ge, and/or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InₓAl_{y}Ga_{1-x-y}N (0≤x≤1, 0≤y≤1, 0≤x+y≤1), and may be formed in a single quantum-well structure or a multi quantum-well structure. In addition, the intermediate layer 233 may include a quantum-wire structure and/or a quantum-dot structure.

Although it is described in FIG. 6A that the first semiconductor layer 231 includes a p-type semiconductor layer and the second semiconductor layer 232 includes an n-type semiconductor layer, the present disclosure is not limited thereto. In another embodiment, the first semiconductor layer 231 may include an n-type semiconductor layer, and the second semiconductor layer 232 may include a p-type semiconductor layer.

Although it is shown in FIG. 6A that the first electrode pad 241 and the second electrode pad 242 are disposed on (or at) the same layer, the present disclosure is not limited thereto. Referring to FIG. 6B, the first electrode pad 241 and the second electrode pad 242 may be disposed on different layers. As an example, a bank layer 230 including an opening overlapping at least a portion of the first electrode pad 241 may be disposed on the first electrode pad 241, and the second electrode pad 242 may be disposed on the upper surface of the bank layer 230. The structure of the light-emitting diode LED shown in FIG. 6B is the same as the structure described above with reference to FIG. 6A.

In another embodiment, as shown in FIG. 6C, the second electrode pads 242 may be disposed on two opposite sides around the first electrode pad 241 in a cross-sectional view. The bank layer 230 may include an opening overlapping at least a portion of the first electrode pad 241, and the second electrode pad 242 may be disposed on the bank layer 230 around the first electrode pad 241. In one or more embodiments, the second electrode pad 242 may have a closed loop shape entirely surrounding the opening of the bank layer 230 and/or the first electrode pad 241. The structure of the light-emitting diode LED shown in FIG. 6C is the same as the structure described above with reference to FIG. 6A.

Although it is shown in FIG. 6A-6C that the first electrode 235 and the second electrode 238 of the light-emitting diode LED face the same direction (e.g., downward direction, −z direction), the present disclosure is not limited thereto. As shown in FIG. 6D, the first electrode 235 and the second electrode 238 of the light-emitting diode LED may face opposite directions.

The bank layer 230 may include an opening exposing at least a portion of the first electrode pad 241, and the thickness of the bank layer 230 may be substantially equal to the thickness of the light-emitting diode LED. A filling material FM may fill the opening of the bank layer 230, and the second electrode pad 242 may be disposed on the upper surface of the bank layer 230 to be electrically connected (e.g., in contact with) the second electrode 238 of the light-emitting diode LED. The filling material may be an organic material having insulating properties.

Although it is shown in FIG. 6A-6D that the light-emitting diode LED is an inorganic light-emitting diode including an inorganic material, the present disclosure is not limited thereto. Referring to FIG. 6E, the light-emitting diode LED may include an organic light-emitting diode (OLED) including an organic material. As an example, the light-emitting diode LED may include the first electrode pad 241 (or first electrode), an organic emission layer 243 overlapping the first electrode pad 241 through the opening of the bank layer 230 disposed on the first electrode pad 241, and the second electrode pad 242 (or second electrode) on the organic emission layer 243. The second electrode pad 242 may be shared by the light-emitting diodes LED. In other words, the second electrode pad 242 of one light-emitting diode LED may be integrally connected to the second electrode pad 242 of another light-emitting diode LED.

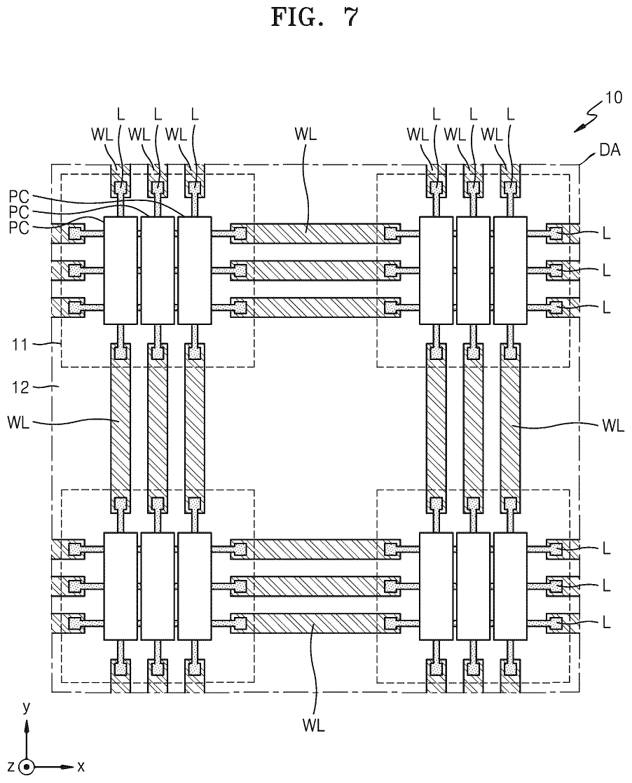

FIG. 7 is a schematic plan view of a portion of the display area DA of the display panel 10 according to one or more embodiments. FIG. 7 shows a conductive line L (referred to as a line, hereinafter) electrically connected to the pixel circuits PC disposed in the display area DA. The pixel circuits PC disposed in each of the first regions 11 shown in FIG. 7 may be electrically connected to light-emitting diodes respectively corresponding to the pixels PXr, PXg, and PXb described with reference to FIG. 3.

Referring to FIG. 7, the pixel circuit PC for driving the light-emitting diode in each pixel may be disposed in the first region 11. With regard to this, FIG. 7 shows three pixel circuits PC are disposed in the first region 11. Like the pixel circuit PC described above with reference to FIG. 5A-5C, each of the pixel circuits PC may include a transistor and a capacitor.

The first region 11 may have an elongation less than an elongation of the second region 12. Accordingly, when the display panel is stretched, the first region 11 may be less transformed than the second region 12. As described above, the first region 11 may be denoted by a low-transformation region (or low-transformation portion). The first region 11 is a region in which the light-emitting diodes are disposed and may be denoted by a pixel area or an emission area.

The second region 12 surrounds the first region 11 and may have an elongation greater than an elongation of the first region 11. The second region 12 may be a region in which main transformation occurs when the display apparatus stretches or shrinks. Because the second region 12 is disposed between the plurality of first regions 11, the second region 12 may be denoted by a connector connecting the first regions 11. The second region 12 may be denoted by a main-transformation region (or a main-transformation portion) or a high-transformation region (or a high-transformation portion). The second region 12 is a region of the display area in which the light-emitting diodes are not disposed and may be denoted by a non-pixel area or a non-emission area.

Lines L electrically connected to the pixel circuit PC may be disposed in the display area DA. In one or more embodiments, it is shown in FIG. 7 that the lines L extending in the first direction (e.g., x direction or −x direction) and the lines L extending in the second direction (e.g., y direction or −y direction) are electrically connected to the pixel circuits PC. Each of the lines L may be electrically connected to the pixel circuit PC through a contact hole.

One of the lines L disposed in the first region 11 may be electrically connected to one of the lines L disposed in the adjacent first region 11 through a connection line WL. The lines L may include a voltage line or a signal line. The lines L may include a gate line that provides gate signals to a gate electrode of a transistor, a data line, and/or a voltage line. In one or more embodiments, the lines L extending in the first direction (e.g., x direction or −x direction) of FIG. 7 may include the gate line (e.g., the scan signal line GWL, the bypass control line GBL, the initialization control line GIL, the emission control line EML, and/or the like) described above with reference to FIG. 5A-5C, and/or the second voltage line VSSL. The lines L extending in the second direction (e.g., y direction or −y direction) may include the data line DL, the first initialization voltage line VIL1, the second initialization voltage line VIL2, the sustain voltage line VSL, and/or the first voltage line VDDL described with reference to FIG. 5A-5C.

The connection line WL disposed in the second region 12 may be stretched better than the lines L disposed in the first region 11. An elongation of each of the connection lines WL may be greater than an elongation of each of the lines L.

The lines L may each include aluminum (Al), platinum (Pt), palladium (Pd), silver (Ag), magnesium (Mg), gold (Au), nickel (Ni), neodymium (Nd), iridium (Ir), chrome (Cr), lithium(Li), calcium (Ca), molybdenum (Mo), titanium (Ti), tungsten (W), and/or copper (Cu). In one or more embodiments, each of the lines L may include a single layer or a plurality of layers including the above metals. In one or more embodiments, each of the lines L may include a metal thin film including a triple layer having a structure of titanium (Ti)/aluminum (Al)/titanium (Ti).

The connection line WL may include liquid metal, a metal nano structure, an elastic polymer, and/or a conductive composite material including elastomer. Accordingly, when the display panel 10 (see FIG. 1) is stretched, high transformation may occur in the connection line WL and the second region 12.

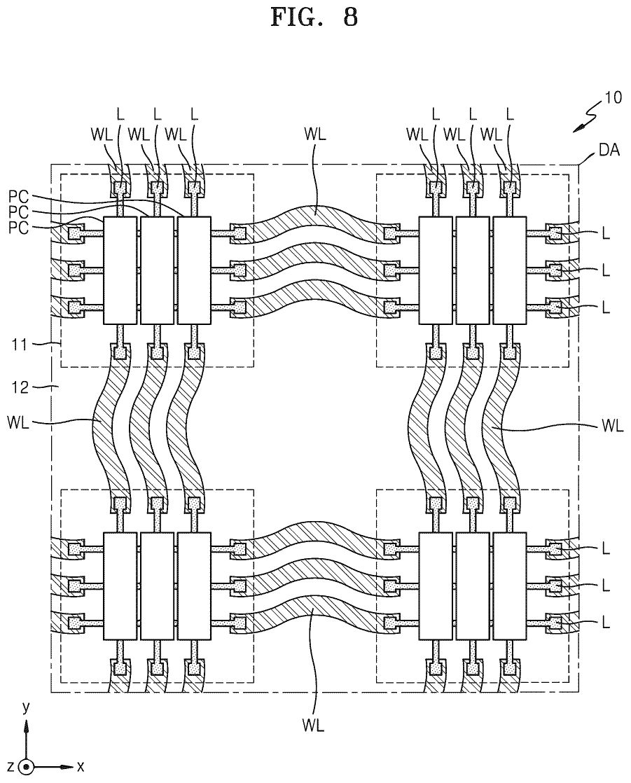

FIG. 8 is a schematic plan view of a portion of the display area DA of the display panel 10 according to one or more embodiments.

Although it is shown in the embodiment described with reference to FIG. 7 that the connection line WL is a straight line in a plan view, the present disclosure is not limited thereto. As shown in FIG. 8, the connection line WL may have a shape other than a straight line in a plan view. The display panel 10 according to the one or more embodiments of FIG. 8 is different from the display panel in FIG. 7 in the shape of the connection line WL in a plan view, and the other constructions are the same as those of the embodiment described above with reference to FIG. 7. Hereinafter, same descriptions are omitted, and differences are mainly described.

Referring to FIG. 8, each of the connection lines WL may have a serpentine shape in a plan view. As an example, each of the connection lines WL may have a wave shape with two or more inflection points in a plan view. In the case where the connection line WL has a serpentine shape, transformation or damage of the connection line WL may be effectively prevented when the second region 12 is stretched. Although it is shown in FIG. 8 that the connection line WL has a gentle C shape in a plan view, the connection line WL may have a wave shape such as an S shape in a plan view in another embodiment.

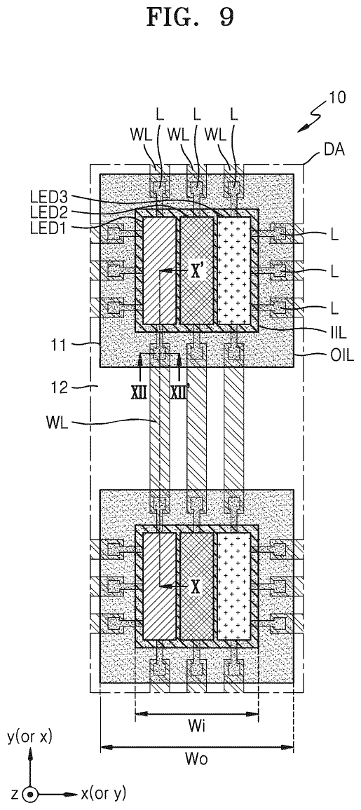

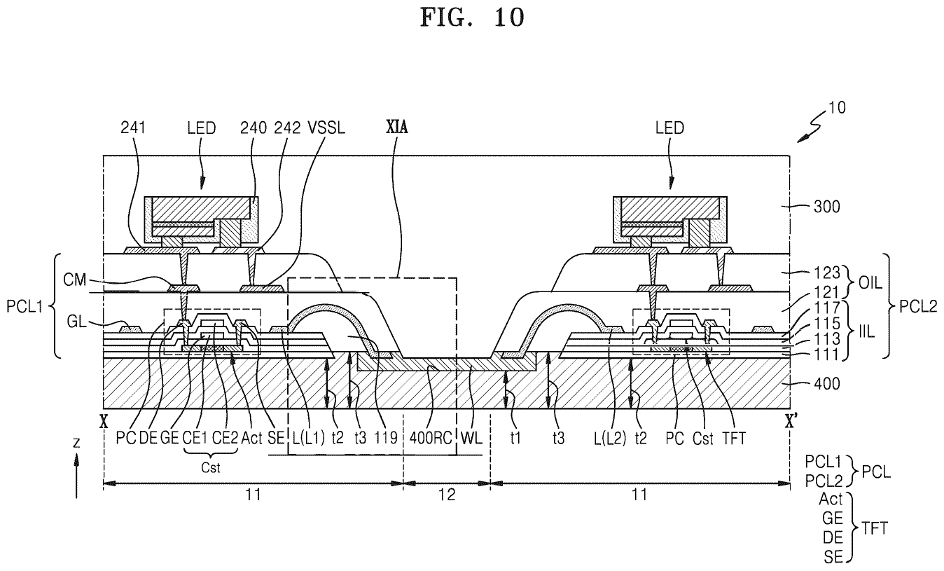

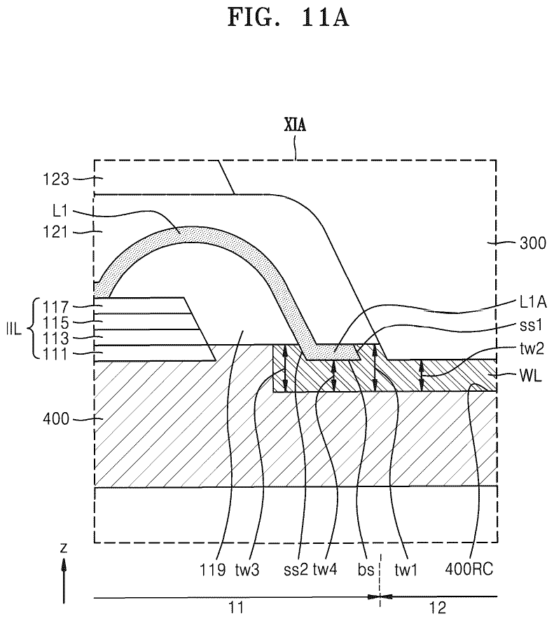

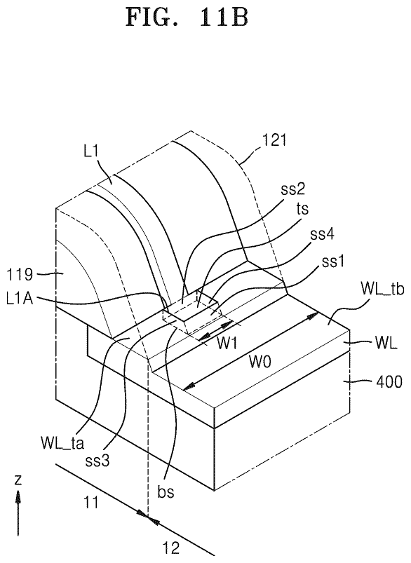

FIG. 9 is an excerpted plan view of a portion of the display panel 10 according to one or more embodiments, and FIG. 10 is a cross-sectional view of the display panel 10, taken along the line X-X′ of FIG. 9. FIG. 11A is an excerpted enlarged cross-sectional view of a region XIA of FIG. 10, and FIG. 11B is a schematic perspective view of FIG. 11A.

Referring to FIG. 9, the light-emitting diodes disposed in the first region 11, for example, the first to third light-emitting diodes LED1, LED2, and LED3 may be electrically respectively connected to the pixel circuits PC (see FIG. 7) described with reference to FIG. 7. The inorganic insulating stack IIL and the organic insulating layer OIL may be disposed in the first region 11. The first to third light-emitting diodes LED1, LED2, and LED3 may be disposed on the inorganic insulating stack IIL and the organic insulating layer OIL.

Referring to FIG. 9, as described above with reference to FIG. 7, the display panel 10 may include the first regions 11 and the second region 12, and a portion of the second region 12 is between the first regions 11. Because the elements of the display panel 10 are disposed on the base layer 400 as shown in FIG. 10, when the display panel 10 includes the first regions 11 and the second region 12, it may mean that the base layer 400 includes the first regions 11 and the second region 12.

Referring to FIG. 10, the display panel 10 may include a pixel circuit layer PCL disposed in each of adjacent two first regions 11, and the light-emitting diode LED on the pixel circuit layer PCL. The light-emitting diode LED on each of the pixel circuit layers PCL shown in FIG. 10 may correspond to one of the first to third light-emitting diodes LED1, LED2, and LED3 shown in FIG. 9.

Each of the pixel circuit layers PCL may include the inorganic insulating stack IIL, the pixel circuit PC, and the organic insulating layer OIL. Hereinafter, for convenience of description, one of the pixel circuit layers PCL disposed in each of the adjacent two first regions 11 is referred to as a first pixel circuit layer PCL1, and the other is referred to as a second pixel circuit layer PCL2.

Each of the first pixel circuit layer PCL1 and the second pixel circuit layer PCL2 may be disposed on the base layer 400. Each of the first pixel circuit layer PCL1 and the second pixel circuit layer PCL2 may be disposed on a first surface (e.g., upper surface) of the base layer 400.

The base layer 400 may absorb stress that occurs while the display panel 10 is stretched. The base layer 400 may include an elastic polymer. The base layer 400 may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and/or Ecoflex™ (Ecoflex™ being a registered trademark of Smooth-On, Inc.).

Each of the first pixel circuit layer PCL1 and the second pixel circuit layer PCL2 may include the inorganic insulating stack IIL, the pixel circuit PC, and the organic insulating layer OIL. The inorganic insulating stack IIL may include a buffer layer 111, a gate insulating layer 113, a first interlayer insulating layer 115, and a second interlayer insulating layer 117. The organic insulating layer OIL may include a first organic insulating layer 121 and a second organic insulating layer 123.

Each of the inorganic insulating stack IIL and the organic insulating layer OIL may have an isolated shape as shown in FIG. 9. Each of the inorganic insulating stack IIL and the organic insulating layer OIL may be disposed in the first region 11. The second region 12 in which the inorganic insulating stack IIL and the organic insulating layer OIL are not present may be relatively easily transformed.

The first region 11 may be defined as a region when the inorganic insulating stack IIL and the organic insulating layer OIL are projected in a direction perpendicular to the base layer 400. In one or more embodiments, in the case where a width Wi of the inorganic insulating stack IIL is less than a width Wo of the organic insulating layer OIL, the width of the organic insulating layer OIL may correspond to the width of the first region 11.

The first pixel circuit layer PCL1 and the second pixel circuit layer PCL2 may be spaced (e.g., spaced apart) from each other. When the first pixel circuit layer PCL1 and the second pixel circuit layer PCL2 are spaced (e.g., spaced apart) from each other, it may denote that the inorganic insulating stack IIL, the pixel circuit PC, and the organic insulating layer OIL of the first pixel circuit layer PCL1 are respectively spaced (e.g., spaced apart) from the inorganic insulating stack IIL, the pixel circuit PC, and the organic insulating layer OIL of the second pixel circuit layer PCL2.

The inorganic insulating stack IIL may be disposed in the first region 11 and may not be disposed in the second region 12. The inorganic insulating stacks IIL disposed in the first regions 11 may be spaced (e.g., spaced apart) from each other in a plan view. As an example, the buffer layer 111, the gate insulating layer 113, the first interlayer insulating layer 115, and the second interlayer insulating layer 117 of the first pixel circuit layer PCL1 may be respectively separated and spaced (e.g., spaced apart) from the buffer layer 111, the gate insulating layer 113, the first interlayer insulating layer 115, and the second interlayer insulating layer 117 of the second pixel circuit layer PCL2.

Likewise, the organic insulating layer OIL may be disposed in the first region 11 and may not be disposed in the second region 12. As an example, the first organic insulating layer 121 and the second organic insulating layer 123 of the first pixel circuit layer PCL1 may be respectively separated and spaced (e.g., spaced apart) from the first organic insulating layer 121 and the second organic insulating layer 123 of the second pixel circuit layer PCL2.

As shown in FIG. 10, the buffer layer 111 may be disposed on the base layer 400, and the pixel circuit PC may be disposed on the buffer layer 111. The buffer layer 111 may include an inorganic insulating material such as silicon oxide, silicon nitride, and/or silicon oxynitride.

A thin-film transistor TFT of the pixel circuit PC may include a semiconductor layer Act, a gate electrode GE, a source electrode SE, and a drain electrode DE. Although FIG. 10 shows a top-gate type thin-film transistor in which the gate electrode GE is disposed on the semiconductor layer Act with the gate insulating layer 113 therebetween, the thin-film transistor TFT may be a bottom-gate type thin-film transistor in another embodiment.

The semiconductor layer Act may include polycrystalline silicon. Alternatively, the semiconductor layer Act may include amorphous silicon, an oxide semiconductor, and/or an organic semiconductor. The gate electrode GE may include a metal thin film including a low-resistance metal material. The gate electrode GE may include a conductive material including molybdenum (Mo), aluminum (Al), copper (Cu), and/or titanium (Ti) and have a single-layered structure or a multi-layered structure including the above materials. As an example, the gate electrode GE may include a metal thin film including a triple layer having a structure of titanium (Ti)/aluminum (Al)/titanium (Ti).

The gate insulating layer 113 between the semiconductor layer Act and the gate electrode GE may include an inorganic insulating material such as silicon oxide, nitrogen oxide, silicon oxynitride, aluminum oxide, and/or titanium oxide. The gate insulating layer 113 may include a single layer or a multi-layer including the above materials.

The source electrode SE and the drain electrode DE may be located on (or at) the same layer, for example, the second interlayer insulating layer 117 and may include the same material. The source electrode SE and the drain electrode DE may include a metal thin film including a low-resistance metal material. The source electrode SE and the drain electrode DE may be connected to a source region and a drain region of the semiconductor layer Act through contact holes, respectively.

The source electrode SE and the drain electrode DE may each include a conductive material including molybdenum (Mo), aluminum (Al), copper (Cu), and/or titanium (Ti) and include a single layer or a multi-layer including the above materials. As an example, like the gate electrode GE, the source electrode SE and the drain electrode DE may include a metal thin film including a triple layer having a structure of titanium (Ti)/aluminum (Al)/titanium (Ti). The second interlayer insulating layer 117 may include an inorganic insulating material such as silicon oxide, nitrogen oxide, silicon oxynitride, aluminum oxide, titanium oxide, and include a single layer or a multi-layer including the above materials.

The storage capacitor Cst may include the first electrode CE1 and the second electrode CE2 overlapping each other with the first interlayer insulating layer 115 therebetween. The storage capacitor Cst may overlap the thin-film transistor TFT. With regard to this, it is shown in FIG. 10 that the gate electrode GE of the thin-film transistor TFT serves as the first electrode CE1 of the storage capacitor Cst. In another embodiment, the storage capacitor Cst may not overlap the thin-film transistor TFT. The storage capacitor Cst may be covered by the second interlayer insulating layer 117.

The first interlayer insulating layer 115 may be disposed between the gate insulating layer 113 and the second interlayer insulating layer 117. Each of the first interlayer insulating layer 115 and the second interlayer insulating layer 117 may include an inorganic insulating material such as silicon oxide, nitrogen oxide, silicon oxynitride, aluminum oxide, titanium oxide, and include a single layer or a multi-layer including the above materials.

The second electrode CE2 of the storage capacitor Cst may include a conductive material and include a single layer or a multi-layer. The second electrode CE2 may include a metal thin film including a low-resistance metal material. The second electrode CE2 may include a conductive material including molybdenum (Mo), aluminum (Al), copper (Cu), and/or titanium (Ti) and have a single-layered structure or a multi-layered structure including the above materials. As an example, the second electrode CE2 may include a metal thin film including a triple layer having a structure of titanium (Ti)/aluminum (Al)/titanium (Ti).

The first organic insulating layer 121 may be disposed on the second interlayer insulating layer 117. The second organic insulating layer 123 may be disposed on the first organic insulating layer 121. A connection electrode CM and the second voltage line VSSL may be disposed on the first organic insulating layer 121.

The connection electrode CM may electrically connect the pixel circuit PC to the first electrode pad 241. The second voltage line VSSL may be electrically connected to the second electrode pad 242.

The connection electrode CM and the second voltage line VSSL may include a metal thin film including a low-resistance metal material. The connection electrode CM and the second voltage line VSSL may each include a conductive material including molybdenum (Mo), aluminum (Al), copper (Cu), and/or titanium (Ti) and include a single layer or a multi-layer including the above materials. As an example, the connection electrode CM and the second voltage line VSSL may include a metal thin film including a triple layer having a structure of titanium (Ti)/aluminum (Al)/titanium (Ti).

The first electrode pad 241 and the second electrode pad 242 may be disposed on the second organic insulating layer 123. The first electrode pad 241 may be electrically connected to the thin-film transistor TFT through the connection electrode CM between the first organic insulating layer 121 and the second organic insulating layer 123.

The light-emitting diode LED on the first electrode pad 241 and the second electrode pad 242 may be the same as the light-emitting diode LED described above with reference to FIG. 6A. In another embodiment, the light-emitting diode LED may have the same structure as the structure of FIG. 6B-6E. One surface of the light-emitting diode LED may be covered by a protective material layer 240 including an organic insulating material, or an inorganic insulating material and an organic insulating material.

In one or more embodiments, the organic insulating layer OIL may further include a third organic insulating layer 119 disposed to cover the lateral surface of the inorganic insulating stack IIL. The third organic insulating layer 119 may have a closed loop shape to cover the lateral surface of the inorganic insulating stack IIL in a plan view. The third organic insulating layer 119 may overlap and/or surround an edge (or the lateral surface) of the inorganic insulating stack IIL. In other words, the third organic insulating layer 119 may have a frame shape in a plan view.

The line L described with reference to FIG. 9 may be electrically connected to the pixel circuit PC of the pixel circuit layer PCL. With regard to this, it is shown in FIG. 10 that a line L1 (referred to as a first line, hereinafter) disposed in one of the first regions 11 from among the lines L of FIG. 9 is electrically connected to the pixel circuit PC of the first pixel circuit layer PCL1, and a line L2 (referred to as a second line, hereinafter) disposed in another of the first regions 11 from among the lines L of FIG. 9 is electrically connected to the second pixel circuit layer PCL2.

The first and second lines L1 and L2 of FIG. 10 may be signal lines or voltage lines. As an example, the first and second lines L1 and L2 may be the gate lines, the data lines DL, the first voltage lines VDDL, the second voltage lines VSSL, the first initialization voltage lines VIL1, the second initialization voltage lines VIL2, the sustain voltage lines VSL, the first voltage lines VDDL, or the second voltage lines VSSL described with reference to FIG. 5A-5C.

Each of the first and second lines L1 and L2 may be disposed on the interlayer insulating layer 117 and may extend toward the connection line WL. As an example, each of the first and second lines L1 and L2 may pass across the upper surface of the relevant third organic insulating layer 119 and extend toward the connection line WL. A portion of each of the first and second lines L1 and L2 may be located between the third organic insulating layer 119 and the first organic insulating layer 121.

A first connection point of the first line L1 and the connection line WL, and a second connection point of the second line L1 and the connection line WL may be located between the inorganic insulating stack IIL of the first pixel circuit layer PCL1 and the inorganic insulating stack IIL of the second pixel circuit layer PCL2. The first connection point of the first line L1 and the connection line WL is a direct contact region of the first connection point of the first line L1 and the connection line WL, and does not overlap the inorganic insulating stack IIL of the first pixel circuit layer PCL1. The second connection point of the second line L2 and the connection line WL is a direct contact region of the second connection point of the second line L2 and the connection line WL, and does not overlap the inorganic insulating stack IIL of the second pixel circuit layer PCL2.

The first organic insulating layer 121 corresponding to the first pixel circuit layer PCL1 passes across the lateral surface of the inorganic insulating stack IIL and extends toward the first connection point of the first line L1 and the connection line WL. The first organic insulating layer 121 corresponding to the second pixel circuit layer PCL2 passes across the lateral surface of the inorganic insulating stack IIL and extends toward the second connection point of the second line L2 and the connection line WL. In other words, the first connection point of the first line L1 and the connection line WL may be covered by the first organic insulating layer 121 corresponding to the first pixel circuit layer PCL1, and the second connection point of the second line L2 and the connection line WL may be covered by the first organic insulating layer 121 corresponding to the second pixel circuit layer PCL2.

At least a portion of a portion (referred to as a first portion, hereinafter) of each of the first and second lines L1 and L2 may be embedded within the connection line WL, and thus, may increase a contact area with the connection line WL. Referring to FIGS. 11A and 11B, a first portion L1A of the first line L1 may be embedded in the connection line WL. A width WO of the connection line WL may be greater than a width W1 of the first portion L1A of the first line L1.

A bottom surface bs of the first portion L1A of the first line L1, and a lateral surface bent with respect to the bottom surface bs may be in direct contact with the connection line WL. As an example, the bottom surface bs of the first portion of the first line L1, a first side surface ss1 facing the first organic insulating layer 121, a second side surface ss2 opposite the first side surface ss1 and facing the inorganic insulating stack IIL, a third side surface ss3 between the first side surface ss1 and the second side surface ss2, and a fourth side surface ss4 opposite the third side surface ss3 may be in direct contact with the connection line WL. The first organic insulating layer 121 may extend on the first portion L1A of the first line L1. The first organic insulating layer 121 may be in direct contact with an upper surface ts (see FIG. 11B) of the first portion L1A of the first line L1.

A first thickness tw1 of a first portion of the connection line WL overlapping the first organic insulating layer 121 and not overlapping the first portion L1A of the first line L1 may be greater than a second thickness tw2 of a second portion of the connection line WL located in the second region 12. The second portion of the connection line WL having the second thickness tw2 may correspond to a portion located between the first organic insulating layer 121 of the first pixel circuit layer PCL1 and the first organic insulating layer 121 of the second pixel circuit layer PCL2.

A third thickness tw3 of the connection line WL overlapping the third organic insulating layer 119 may be greater than the second thickness tw2. A fourth thickness tw4 of a fourth portion of the connection line WL overlapping the first portion L1A, for example, the bottom surface bs of the first line L1, may be less than the first thickness tw1 and/or the third thickness tw3.

A portion of the connection line WL, for example, a portion of the connection line WL overlapping the first organic insulating layer 121 and/or the third organic insulating layer 119 in the first region 11, may protrude more in a third direction (e.g., z direction) than a portion of the connection line WL located in the second region 12. In other words, the upper surface of the connection line WL may have a step difference. In other words, an upper surface WL_ta of a portion of the connection line WL located in the first region 11 may have a step difference with respect to an upper surface WL_tb of a portion of the connection line WL located in the second region 12. In addition, although FIGS. 11A and 11B show the first line L1 and the connection line WL, the present disclosure is not limited thereto. The structures of the second line L2 and the connection line WL are substantially equal to the structure of FIGS. 11A and 11B.

Referring to FIG. 10 again, the connection line WL may be embedded in the base layer 400. The base layer 400 may include a first surface (e.g., upper surface) facing the first pixel circuit layer PCL1 and the second pixel circuit layer PCL2, and a second surface (e.g., lower surface) opposite the first surface. The base layer 400 may include a recess (or concave portion) 400RC concave with respect to the first surface, and the connection line WL may be present in the recess 400RC. As an example, the connection line WL may fill the recess 400RC. Because the connection line WL has a structure embedded in the base layer 400, the base layer 400 may absorb stress that may be concentrated on the connection line WL while the display panel 10 is stretched.

The connection line WL may include a lower surface facing the base layer 400, and an upper surface opposite the lower surface. The upper surface of the connection line WL may have a step difference as described above with reference to FIGS. 11A and 11B. The lower surface of the connection line WL facing the base layer 400 may have a level between the upper surface and the lower surface of the base layer 400. The lower surface of the connection line WL may have a substantially flat surface.

Although the lower surface of the base layer 400 may have a substantially flat surface, the upper surface of the base layer 400 may include a step difference. A thickness t1 of a first portion of the base layer 400 overlapping the connection line WL may be less than a thickness t2 of a second portion of the base layer 400 overlapping the inorganic insulating stack IIL.

In one or more embodiments, a thickness t3 of a third portion of the base layer 400 disposed between the inorganic insulating stack IIL and the connection line WL may be greater than the thickness t2 of the second portion of the base layer 400. The third portion of the base layer 400 may be in direct contact with a portion of the lateral surface of the inorganic insulating stack IIL. Although it is shown in FIG. 10 that the third portion of the base layer 400 is in contact with the lateral surface of the buffer layer 111 of the inorganic insulating stack IIL, the present disclosure is not limited thereto. In another embodiment, the third portion of the base layer 400 is in direct contact with the lateral surface of the buffer layer 111, the gate insulating layer 113, and/or the like of the inorganic insulating stack IIL.

Although it is shown in FIG. 10 that two opposite edges of the connection line WL overlap the third organic insulating layer 119, the present disclosure is not limited thereto. In another embodiment, the connection line WL may extend toward the inorganic insulating stack IIL such that the two opposite edges of the connection line WL overlap the inorganic insulating stack IIL of the first and second pixel circuit layers PCL1 and PCL2. In this case, the connection line WL may be in direct contact with the bottom surface of the inorganic insulating stack IIL.

The light-emitting diode LED may be disposed on the pixel circuit layer PCL. As an example, the light-emitting diode LED electrically connected to the pixel circuit PC of the first pixel circuit layer PCL1 may be disposed on the relevant first pixel circuit layer PCL1, and the light-emitting diode LED electrically connected to the pixel circuit PC of the second pixel circuit layer PCL2 may be disposed on the relevant second pixel circuit layer PCL2. One surface of each light-emitting diode LED may be covered by the protective material layer 240. The protective material layer 240 may include an organic insulating material such as polyimide.

A protective layer 300 may be disposed on the light-emitting diode LED and the connection line WL. The protective layer 300 may cover the light-emitting diode LED and the connection line WL.

The protective layer 300 may absorb stress that may be transferred to the light-emitting diode LED and the connection line WL while the display panel 10 is stretched, and may planarize the upper surface of the display panel 10. The protective layer 300 may include an elastic polymer. For example, the protective layer 300 may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and/or Ecoflex™ (Ecoflex™ being a registered trademark of Smooth-On, Inc.).

In one or more embodiments, the protective layer 300 may be in direct contact with a portion of the upper surface of the connection line WL, and may be in direct contact with a portion (e.g., a portion and/or the like of the upper surface of the base layer 400 located between the connection line WL and the connection line WL shown in FIG. 9) of the upper surface of the base layer 400. In one or more embodiments, in the case where a material of the protective layer 300 is the same as a material of the base layer 400, because bonding force between the protective layer 300 and the base layer 400 may be increased, airtightness of the display panel 10 may be more effectively maintained.

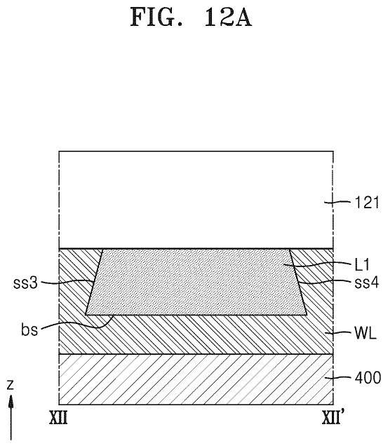

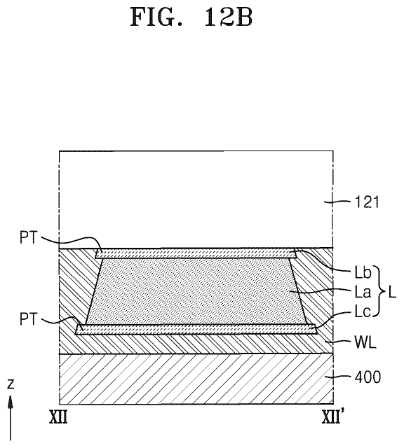

FIGS. 12A and 12B are cross-sectional views of the display panel 10, taken along the line XII-XII′ of FIG. 9.

The bottom surface bs and lateral surface of the first portion of the line L may be in direct contact with the connection line WL. With regard to this, it is shown in FIG. 12A that the bottom surface bs, third side surface ss3, and fourth side surface ss4 of the first portion of the line L are in direct contact with the connection line WL.

In one or more embodiments, as shown in FIG. 12A, the line L may be a single layer including metal. In one or more embodiments, as shown in FIG. 12B, the line L may have a multi-layered structure including different metals. As an example, the line L may include a first layer La, a second layer Lb disposed on the upper surface of the first layer La, and a third layer Lc disposed on the lower surface of the first layer La. The connection line WL may be in direct contact with the lateral surface of each of the first layer La, the second layer Lb, and the third layer Lc, and the bottom surface of the third layer Lc. Although it is shown in FIG. 12B that the line L includes three layers, the present disclosure is not limited thereto. In another embodiment, the line L may have a two-layered structure including the first layer La and the second layer Lb disposed on the upper surface of the first layer La.

The first layer La may include a material with a material having a different etching selectivity than etching selectivity of the second layer Lb and/or the third layer Lc. As an example, the first layer La may include aluminum, the second layer Lb and/or third layer Lc may include titanium. The second layer Lb may include a tip PT protruding in a lateral direction from a point where the lateral surface of the first layer La meets the bottom surface of the second layer Lb. Similarly, the third layer Lc may include a tip PT protruding in a lateral direction from a point where the lateral surface of the first layer La meets the upper surface of the third layer Lc. The connection line WL may be in direct contact with the lateral surfaces and bottom surface of the tips PT of the second layer Lb and the third layer Lc. Because the second layer Lb and/or third layer Lc include the tip PT as described above, bonding force between the connection line WL and the line L may be increased. The structure of the tip PT of the second layer Lb may correspond to a kind of anchor structure, and thus, further improve bonding force between the line L and the connection line WL surrounding the lateral surfaces of the line L and in contact with the lateral surfaces of the line L.

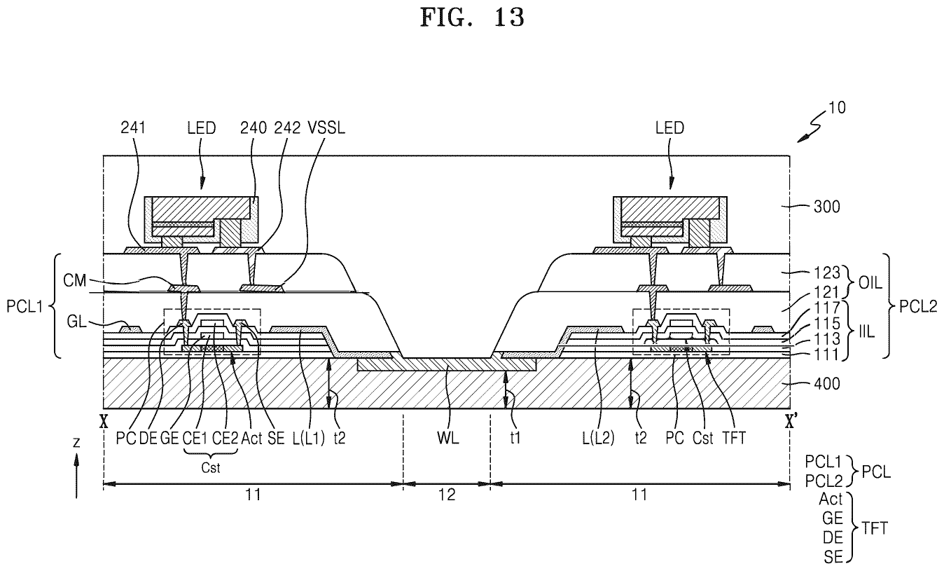

FIG. 13 is a cross-sectional view of a portion of the display panel 10, and shows a cross-section taken along the line X-X′ of FIG. 9, according to one or more embodiments.

Although the organic insulating layer OIL of the display panel 10 according to the embodiment described with reference to FIG. 10 includes the third organic insulating layer 119 covering the lateral surface of the inorganic insulating stack IIL, the present disclosure is not limited thereto. The organic insulating layer OIL of the display panel 10 according to the embodiment described with reference to FIG. 13 does not include the third organic insulating layer 119 (see FIG. 10). Because the display panel 10 according to the embodiment described with reference to FIG. 13 has substantially the same structure described with reference to FIG. 10, differences are mainly described below.

Referring to FIG. 13, the first line L1 may extend on the connection line WL while being in contact with the lateral surface of the relevant inorganic insulating stack IIL, and the second line L2 may extend on the connection line WL while being in contact with the lateral surface of the relevant inorganic insulating stack IIL. The first organic insulating layer 121 of the first pixel circuit layer PCL1 may have a width greater than the width of the inorganic insulating stack IIL. The first organic insulating layer 121 may cover the first connection point of the first line L1 and the connection line WL. Likewise, the first organic insulating layer 121 of the second pixel circuit layer PCL2 may have a width greater than the width of the inorganic insulating stack IIL. The first organic insulating layer 121 may cover the second connection point of the second line L2 and the connection line WL.

As described above with reference to FIGS. 11A and 11B, the connection line WL may be in direct contact with the bottom surface and the lateral surface of the first portion of each of the first and second lines L1 and L2. The upper surface of the connection line WL may have a step difference structure as described with reference to FIGS. 11A and 11B.

Although it is shown in FIG. 13 that the connection line WL is in contact with a portion of the bottom surface of the first portion of each of the first and second lines L1 and L2, the present disclosure is not limited thereto. In another embodiment, the connection line WL may extend on the bottom surface of the inorganic insulating stack IIL of each of the first and second pixel circuit layers PCL1 and PCL2, and may be in contact with the entire bottom surface of the first portion of each of the first and second lines L1 and L2.

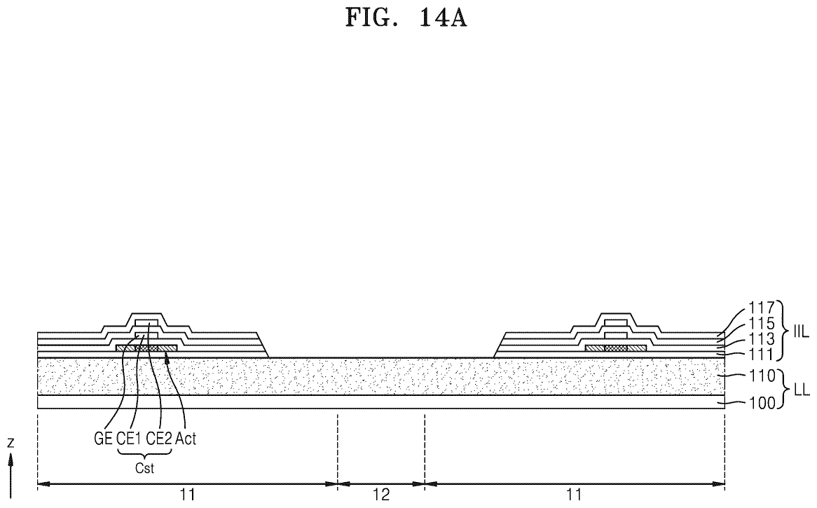

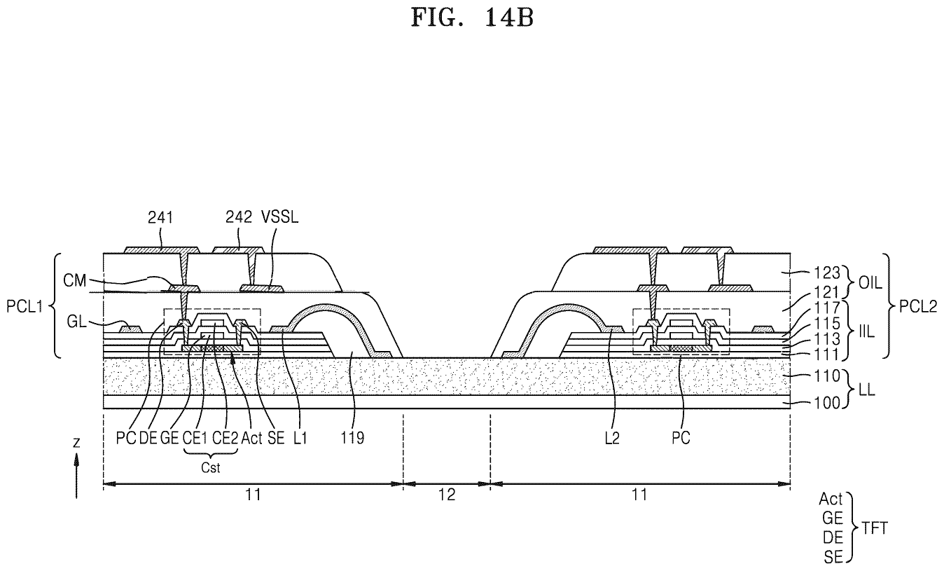

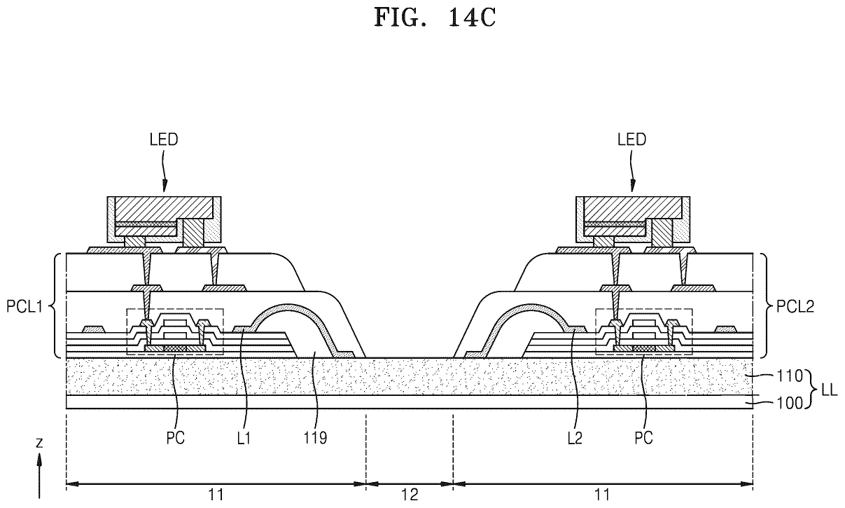

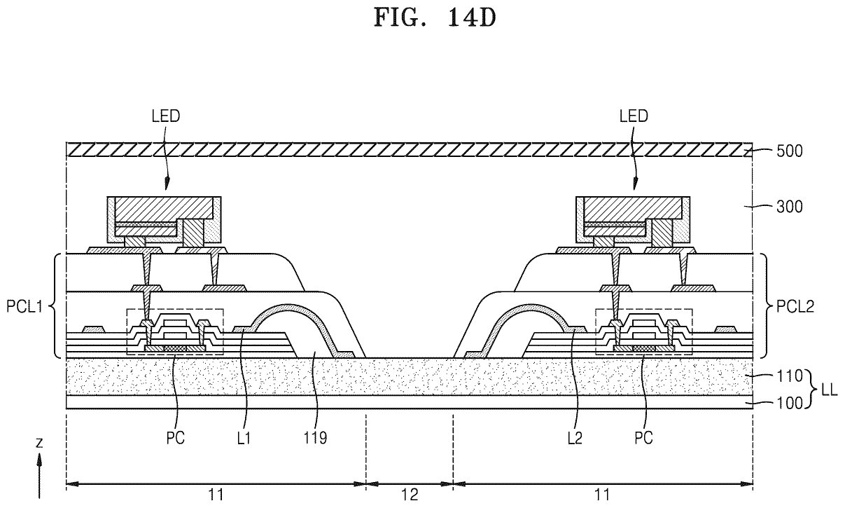

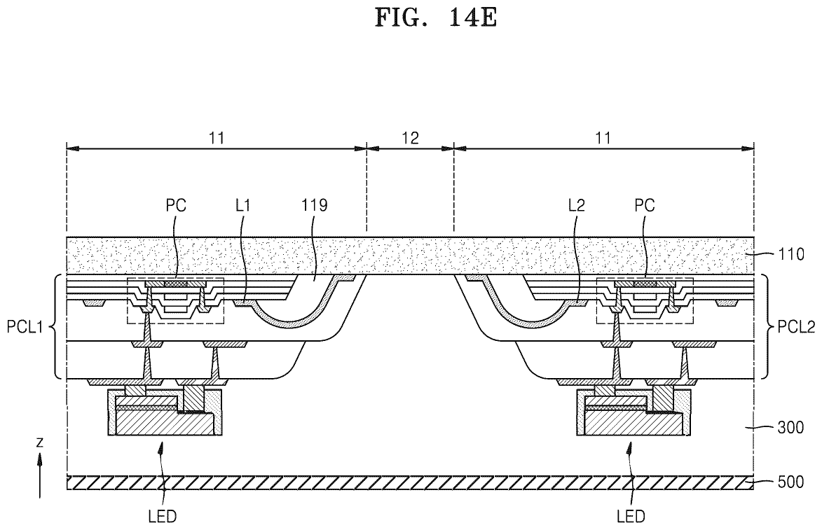

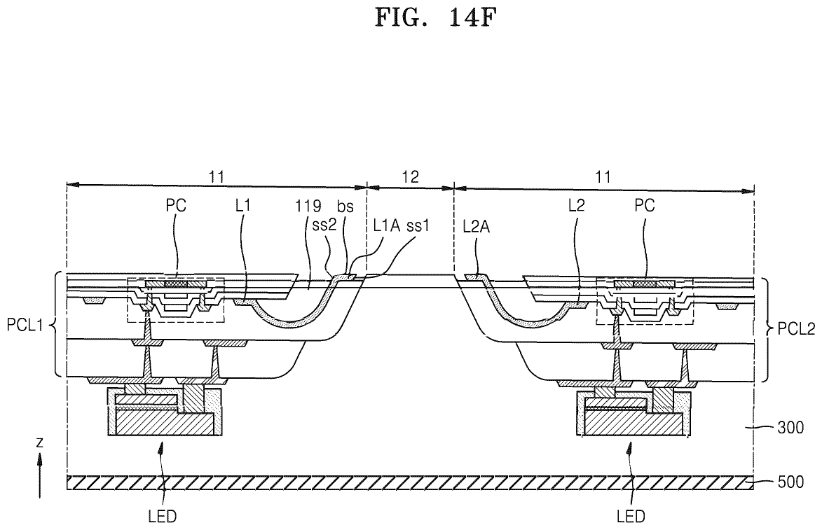

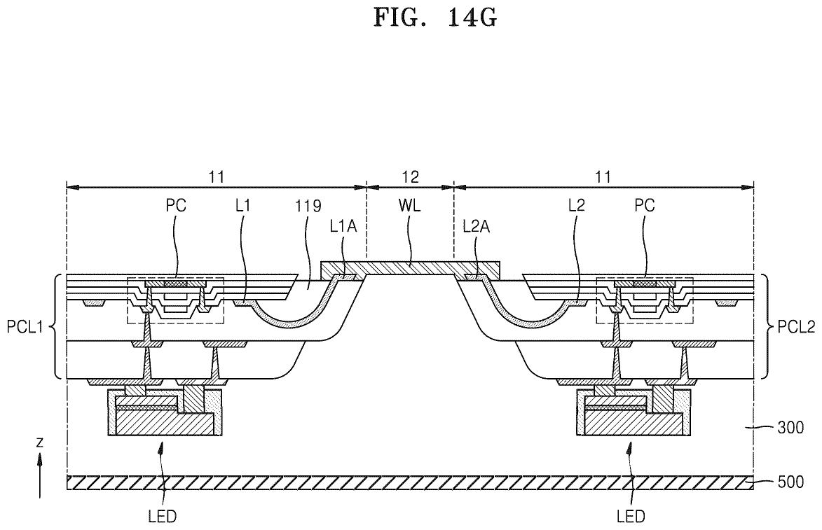

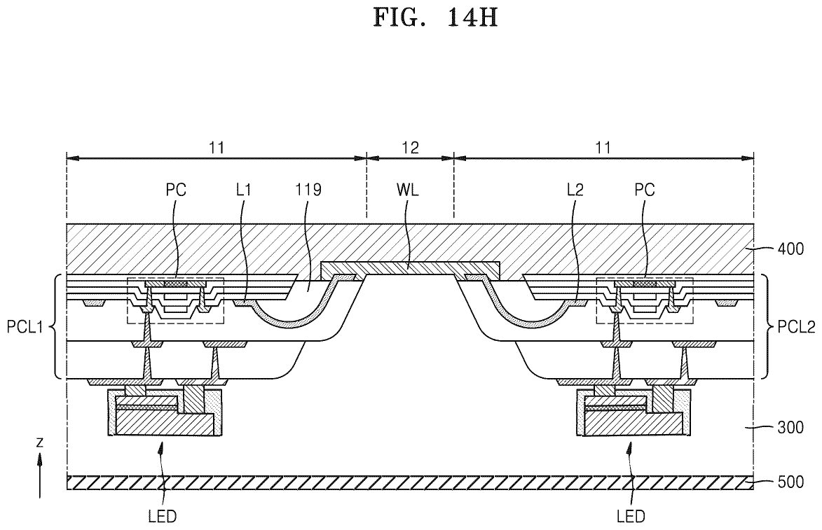

FIG. 14A-14H are cross-sectional views showing processes corresponding to a method of manufacturing the display panel 10 according to one or more embodiments.

Referring to FIG. 14A, a carrier layer LL may be prepared. In one or more embodiments, the carrier layer LL may include a substrate 100 and a resin layer 110 dispose on the substrate 100. The substrate 100 may be a rigid substrate. As an example, the substrate 100 may be a transparent glass substrate including SiO₂ as a main component, or a substrate including a polymer resin material such as reinforced plastic. The resin layer 110 may include a polymer resin. As an example, the resin layer 110 may include polyethersulfone, polyacrylate, polyetherimide, polyethylene naphthalate, polyethylene terephthalate, polyphenylene sulfide, polyarylate, polyimide, polycarbonate, cellulose acetate propionate, and/or the like. In one or more embodiments, the thickness of the resin layer 110 may be greater than the thickness of the substrate 100.

The inorganic insulating stack IIL, the storage capacitor Cst, and a portion of the thin-film transistor TFT (see FIG. 10) may be formed on the carrier layer LL. As an example, the buffer layer 111, the semiconductor layer Act, the gate insulating layer 113, the gate electrode GE, the first interlayer insulating layer 115, the second electrode CE2, and the second interlayer insulating layer 117 may be formed on the carrier layer LL.

The inorganic insulating stack IIL may be disposed in only the first region 11 and may not be disposed in the second region 12. As an example, a portion of the inorganic insulating stack IIL overlapping the second region 12 may be removed through an etching process.

Referring to FIG. 14B, the third organic insulating layer 119 may be formed on the second interlayer insulating layer 117. The third organic insulating layer 119 may cover the lateral surface of the inorganic insulating stack IIL. The source electrode SE and the drain electrode DE may be disposed on the second interlayer insulating layer 117.

The first line L1 and the second line L2 may be formed. The first line L1 may be located on the relevant second interlayer insulating layer 117, may pass across the upper surface of the third organic insulating layer 119, and extend on the upper surface of the resin layer 110. The second line L2 may be located on the relevant second interlayer insulating layer 117, may pass across the upper surface of the third organic insulating layer 119, and extend on the first surface (e.g., surface in contact with the buffer layer 111) of the resin layer 110.

The first organic insulating layer 121 may be formed on the pixel circuit PC, and the connection electrode CM and the second voltage line VSSL may be formed on the first organic insulating layer 121. The second organic insulating layer 123 may be formed on the connection electrode CM, and the first electrode pad 241 and the second electrode pad 242 may be formed on the second organic insulating layer 123. The source electrode SE and the drain electrode DE of the thin-film transistor TFT may also be formed on the second interlayer insulating layer 117.

Although FIG. 14B shows a structure in which the third organic insulating layer 119 is formed, the present disclosure is not limited thereto. In another embodiment, as shown in FIG. 13, the third organic insulating layer 119 may not be formed. In this case, each of the first line L1 and the second line L2 may extend on the first surface of the resin layer 110 while being in direct contact with the lateral surface of the relevant inorganic insulating stack IIL.

Referring to FIG. 14C, the light-emitting diodes LED may be respectively formed on the first pixel circuit layer PCL1 and the second pixel circuit layer PCL2 described with reference to FIG. 14B. The light-emitting diode LED may be an inorganic light-emitting diode described with reference to FIG. 6A-6D, or an organic light-emitting diode (OLED) described with reference to FIG. 6E.

Referring to FIG. 14D, the protective layer 300 may be formed on the light-emitting diode LED. The protective layer 300 may include the same material as the material described with reference to FIG. 10. During the process, the protective layer 300 may be in direct contact with the resin layer 110. The protective layer 300 may be formed by depositing a material (e.g., an elastic polymer) forming the protective layer 300 and curing the material. For the curing process, heat or light such as ultraviolet light may be used.

A carrier film 500 may be formed on the protective layer 300. In one or more embodiments, an adhesive layer may be further disposed between the protective layer 300 and the carrier film 500. The carrier film 500 may protect the protective layer 300 from scratches, chopping, and/or the like that occur while the process is performed. As an example, the carrier film 500 may include an insulating material.

Referring to FIG. 14E, after reversing the structure upside down according to the process of FIG. 14D, the substrate 100 may be removed from the resin layer 110. Bonding force between the substrate 100 and the resin layer 110 may be weakened by irradiating a laser beam to the other surface of the substrate 100 opposite the one surface of the substrate 100 in contact with the resin layer 110. Accordingly, the substrate 100 may be separated and removed from the resin layer 110. However, this is just an example, and a method of removing the substrate 100 may be variously changed.

Referring to FIG. 14F, the resin layer 110 may be removed. The resin layer 110 may be removed through a dry etching process. When the resin layer 110 is removed, one surface (e.g., surface located opposite a surface facing the light-emitting diode LED) of the first pixel circuit layer PCL1 and the second pixel circuit layer PCL2 may be exposed. As an example, one surface (e.g., surface located opposite a surface facing the first organic insulating layer 121) of the inorganic insulating stack IIL of each of the first pixel circuit layer PCL1 and the second pixel circuit layer PCL2, one surface of a portion of the first organic insulating layer 121 of each of the first pixel circuit layer PCL1 and the second pixel circuit layer PCL2, and one surface of a portion of each of the first line L1 and the second line L2 may be exposed.

When removing the resin layer 110, a portion of the first organic insulating layer 121 and a portion of the third organic insulating layer 119 are removed together. The resin layer 110, a portion of the first organic insulating layer 121, and a portion of the third organic insulating layer 119 may be removed by the same gas. Because a portion of the first organic insulating layer 121 and a portion of the third organic insulating layer 119 are removed, the bottom surface bs and lateral surfaces of the first portions L1A and L2A of the first and second lines L1 and L2 may be exposed to the outside. With regard to this, it is shown in FIG. 14F that the bottom surface bs, first side surface ss1, and second side surface ss2 of the first portions L1A and L2A of the first and second lines L1 and L2 are exposed.

The bottom surface bs of the first portions L1A and L2A of the first and second lines L1 and L2, and one surface of the inorganic insulating stack IIL may be located on (or at) the same plane. However, because a portion of the first organic insulating layer 121 and a portion of the third organic insulating layer 119 are removed, one surface of a portion of the first organic insulating layer 121 and one surface of a portion of the third organic insulating layer 119 are not located on (or at) the same plane as one surface of the inorganic insulating stack IIL.

Referring to FIG. 14G, the connection line WL may be formed. The connection line WL may be in direct contact with the first portion L1A of the first line L1 and the first portion L2A of the second line L2 that are exposed to the outside. As an example, the connection line WL may be in direct contact with the bottom surface and lateral surfaces of the first portions L1A and L2A of the first and second lines L1 and L2.

The connection line WL may be disposed in the second region 12 between adjacent two first regions 11, and may extend from one of the adjacent two first regions 11 to the other.

In one or more embodiments, the connection line WL may include liquid metal, a metal nano structure, an elastic polymer, and/or a conductive composite material including elastomer. The connection line WL may be formed through a vacuum deposition process, a printing process, coating, and/or the like.

Referring to FIG. 14H, the base layer 400 may be formed on the connection line WL. The base layer 400 may be disposed to cover the connection line WL. The base layer 400 may include the same material as the material described with reference to FIG. 10. The base layer 400 may support the elements of the display panel 10 (see FIG. 10) and absorb stress that may occur while the display panel 10 (see FIG. 10) is stretched.

The structure of FIG. 14H may be reversed as shown in FIG. 10, and the display panel 10 shown in FIG. 10 may be formed by removing the carrier film 500. The carrier film 500 (see FIG. 14H) may be removed using an exfoliation tape.

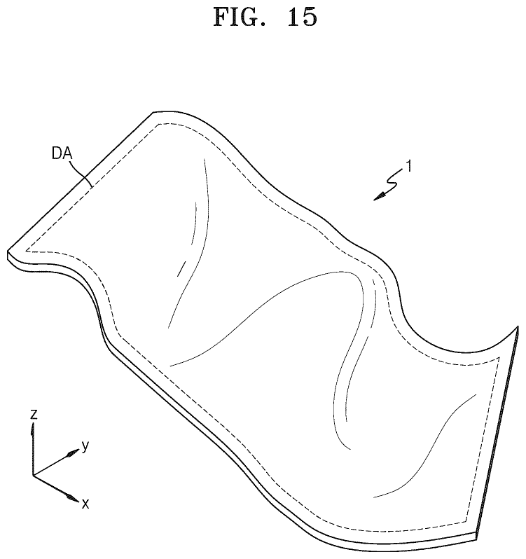

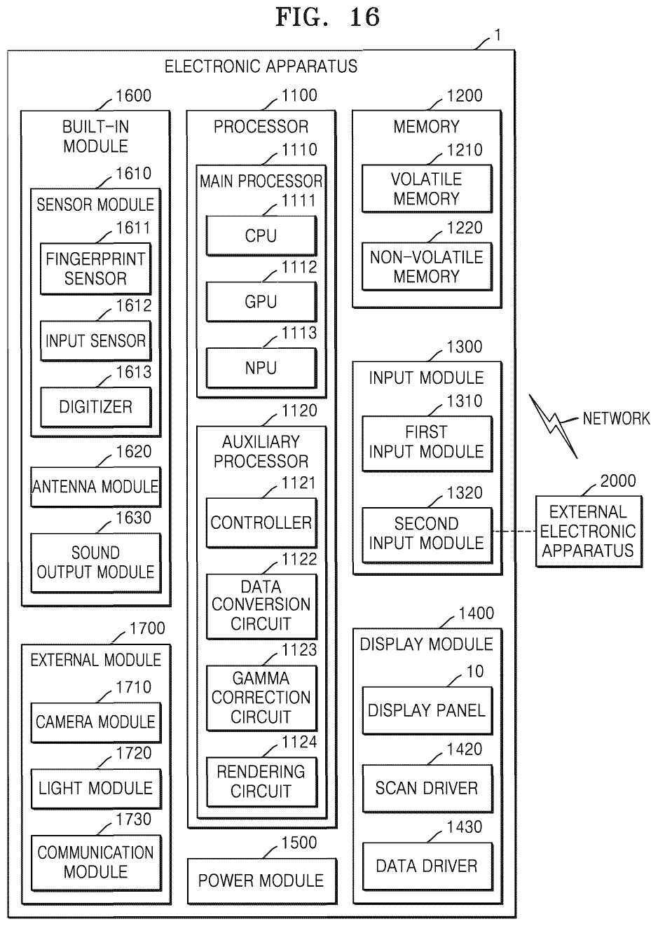

FIG. 15 is a schematic perspective view of an electronic apparatus 1 including the display panel 10 according to one or more embodiments, and FIG. 16 is a block diagram of the electronic apparatus 1 including the display panel 10 according to one or more embodiments.

Referring to FIG. 15, the electronic apparatus 1 is freely transformed three-dimensionally, and may provide a three-dimensional image surface through the display area DA. When the electronic apparatus 1 is freely transformed three-dimensionally, it is distinguished from an operation of an electronic apparatus having a rollable display panel such as a case where only a portion of a rolled-up display area is visible to a user and then another portion of the rolled-up display area is unfolded so that the entire display area is visible to the user (or a case where the entire unfolded display area is visible to the user and then the display area is rolled-up so that only a portion of the display area is visible to the user). The electronic apparatus 1 according to one or more embodiments may represent transformation such as a case where the area of the entire display area DA increases or decreases again while the electronic apparatus 1 is transformed in the x direction, y direction, and/or z direction.

Referring to FIG. 16, the electronic apparatus 1 may include a processor 1100, a memory 1200, an input module 1300, a display module 1400, a power module 1500, a built-in module 1600, and an external module 1700. According to one or more embodiments, in the electronic apparatus 1, at least one of the elements may be omitted, or one or more other elements may be added. According to one or more embodiments, some (e.g., the built-in module 1600) of the elements may be integrated into another element (e.g., the display module 1400).

The processor 1100 may control at least one other element (e.g., a hardware or software element) of the electronic apparatus 1 connected to the processor 1100 by executing software, and perform various data processes or operations. According to one or more embodiments, as at least some of data processes or operations, the processor 1100 may store commands or data received from another element (e.g., the input module 1300, a sensor module 1610, and/or a communication module 1730) in a volatile memory 1210, process the commands or data stored in the volatile memory 1210, and store result data in a non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphic processing unit (GPU) 1112, a communication processor (CP), and an image signal processor (ISP). The main processor 1110 may further include a neural processing unit (NPU) 1113. The NPU is a processor specialized in processing artificial intelligence models, and the artificial intelligence models may be created through machine learning. The artificial intelligence models may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, and a combination of two or more of the above, but is not limited to the examples described above. The artificial intelligence models may additionally or alternatively include a software structure in addition to a hardware structure. At least two of the processing units and the processors may be implemented as one integrated construction (e.g., a single chip) or respectively implemented as independent constructions (e.g., a plurality of chips).

The auxiliary processor 1120 may include a controller 1121. The controller 1121 may include an interface conversion circuit and a timing control circuit. The controller 1121 receives image signals from the main processor 1110, converts a data format of image signals to match interface specifications of the display module 1400, and outputs image data. The controller 1121 may output various kinds of control signals required for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, correct image data such that images are displayed at desired brightness according to characteristics of the electronic apparatus 1, a user's settings, and/or the like, or convert image data to reduce power consumption or compensate for an afterimage. The gamma correction circuit 1123 may convert image data, a gamma reference voltage, and/or the like such that images displayed by the electronic apparatus 1 have desired gamma characteristics. The rendering circuit 1124 may receive image data from the controller 1121, and render the image data by taking into account the pixel configuration of the display panel 10 applied to the electronic apparatus 1. At least one of the data conversion circuit 1122, the gamma correction circuit 1123, and the rendering circuit 1124 may be integrated into another element (e.g., the main processor 1110 or the controller 1121). In one or more embodiments, the auxiliary processor 1120 may be integrated into a data driver 1430.

The memory 1200 may store various data and input data or output data for commands related thereto, wherein the various data are used by at least one element (e.g., the processor 1100 or the sensor module 1610) of the electronic apparatus 1. The memory 1200 may include at least one of the volatile memory 1210 and the non-volatile memory 1220.

The input module 1300 may receive commands or data from the outside (e.g., a user or an external electronic apparatus 2000) of the electronic apparatus 1, wherein the commands or data are to be used by the element (e.g., the processor 1100, the sensor module 1610, or a sound output module 1630) of the electronic apparatus 1.

The input module 1300 may include a first input module 1310 to which commands or data from a user are input, and a second input module 1320 to which commands or data from the external electronic apparatus 2000 are input.

The first input module 1310 may include a microphone, a mouse, a keyboard, and/or a pen (e.g., a passive pen or active pen). The first input module 1310 may include a mechanical input means such as buttons, a dome switch, a jog wheel, a jog switch, and/or the like, or a touch input means located on the lower surface or the lateral surface of the electronic apparatus 1. The touch input means may include the touchscreen layer of the display panel 10.

The second input module 1320 may be connected to various kinds of external electronic apparatuses 2000 connected to the electronic apparatus 1 via wires or wirelessly. In one or more embodiments, the second input module 1320 may include a high definition multimedia interface (HDMI), a universal serial bus (USB) interface, a secure digital (SD) card interface, and/or an audio interface. The second input module 1320 may include a connector that may physically connect the electronic apparatus 1 to the external electronic apparatus 2000, wherein the connector includes an HDMI connector, a USB connector, an SD card connector, and/or an audio connector (e.g., a headphone connector). The electronic apparatus 1 may perform appropriate control related to the connected external electronic apparatus 2000 in response to the external electronic apparatus 2000 being connected to the second input module 1320.

The display module 1400 provides a user with visual information. The display module 1400 may include the display panel 10, a scan driver 1420, and the data driver 1430.

The display panel 10 displays (outputs) information processed by the electronic apparatus 1. The display panel 10 may display execution screen information of an application driven in the electronic apparatus 1, or user interface (UI) and graphic user interface (GUI) information corresponding to the execution screen information.

The scan driver 1420 may be mounted on the display panel 10 as a driving chip. Alternatively, the scan driver 1420 may be directly formed on the display panel 10. As an example, the scan driver 1420 may include an amorphous silicon thin-film transistor (TFT) gate driver circuit (ASG), a low temperature polycrystalline silicon (LTPS) TFT gate driver circuit, and/or an oxide semiconductor TFT gate (OSG) driver circuit embedded in the display panel 10. The scan driver 1420 receives control signals from the controller 1121 and outputs scan signals to the display panel 10 in response to control signals.

The display panel 10 may further include an emission control driver. The emission control driver outputs an emission control signal to the display panel 10 in response to a control signal received from the controller 1121. The emission control driver may be formed separately from the scan driver 1420 or integrated in the scan driver 1420.

The data driver 1430 receives a control signal from the controller 1121, converts image data into a data voltage in the form of an analog voltage in response to a control signal, and outputs data voltages to the display panel 10.

The data driver 1430 may be integrated into some elements of the auxiliary processor 1120. As an example, the data driver 1430 may be provided in a timing controller embedded driver IC including the controller 1121.

The power module 1500 supplies power to the elements of the electronic apparatus 1. The power module 1500 may include a battery charging a power voltage. In addition, the power module 1500 has a connection port, and the connection port may be included in the second input module 1320 to which an external charger that supplies power to charge the battery is connected. Alternatively, the power module 1500 may include a wireless power transmission/reception member to charge the battery wirelessly. The wireless power transmission/reception member may include a plurality of coil-shaped antenna radiators. The power module 1500 may include a power management integrated circuit (PMIC). The PMIC supplies power optimized for each of the elements of the electronic apparatus 1.

The electronic apparatus 1 may further include the built-in module 1600 and the external module 1700. The built-in module 1600 may include the sensor module 1610, an antenna module 1620, and the sound output module 1630. The external module 1700 may include a camera module 1710, a light module1720, and/or the communication module 1730.

The sensor module 1610 may include touch electrodes of the touchscreen layer of the display panel 10, and the touch sensor driver. The sensor module 1610 may sense an input due to a user's body or an input due to a pen, and generate an electrical signal or a data value corresponding to the input. The sensor module 1610 may include at least one of a fingerprint sensor 1611, an input sensor 1612, and a digitizer 1613.

The fingerprint sensor 1611 may generate a data value corresponding to a user's fingerprint. The fingerprint sensor 1611 may include one of an optical fingerprint sensor and a capacitive fingerprint sensor.

The input sensor 1612 may generate a data value corresponding to coordinate information of an input due to a user's body or an input due to a pen. The input sensor 1612 generates an amount of change in a capacitance due to an input as a data value. The input sensor 1612 may sense an input due to a passive pen or transmit/receive data to/from an active pen.

The input sensor 1612 may also measure biological signals such as blood pressure, moisture, and/or body fat. As an example, in the case where a user touches a portion of the user's body to a sensor layer or sensing panel and does not move for a preset time, the input sensor 1612 may sense biosignals based on a change in the electric field caused by the portion of the user's body, and output information desired by the user to the display module 1400.

The digitizer 1613 may generate a data value corresponding to coordinate information of an input due to a pen. The digitizer 1613 generates a change in electromagnetism due to an input as a data value. The digitizer 1613 may sense an input due to a passive pen or transmit/receive data to/from an active pen.

In one or more embodiments, at least one of the fingerprint sensor 1611, the input sensor 1612, and the digitizer 1613 may be built into the display panel 10. As an example, at least one of the fingerprint sensor 1611, the input sensor 1612, and the digitizer 1613 may be formed during a process that is successive to the process of forming the pixel circuits and the light-emitting diodes of the display panel 10. Accordingly, the display panel 10 may serve as one of the input modules 1300 that provide an input interface between the electronic apparatus 1 and a user, and concurrently (e.g., simultaneously), serve as the display module 1400 that provides an output interface between the electronic apparatus 1 and a user.

In one or more embodiments, at least two of the fingerprint sensor 1611, the input sensor 1612, and the digitizer 1613 may be formed to be integrated in one sensing panel through the same process. Although the sensing panel may be disposed between the display panel 10 and the cover window disposed on the display panel 10, the present disclosure is not limited thereto.

The antenna module 1620 may include at least one antenna for transmitting signals or power to the outside or receiving signals or power from the outside. In one or more embodiments, the communication module 1730 may transmit signals to an external electronic apparatus or receive signals from an external electronic apparatus through an antenna suitable for a communication method. An antenna pattern of the antenna module 1620 may be integrated in one element (e.g., the display panel 10) of the display module 1400 or the input sensor 1612.

The sound output module 1630 is a device for outputting sound signals to the outside of the electronic apparatus 1, and may output sound data received from the communication module 1730 or stored in the memory 1200 during call signal reception, a communication mode or recording mode, a voice recognition mode, a broadcasting reception mode, and/or the like. The sound output module 1630 may output sound signals related to a function (e.g., a call signal reception tone, a message reception tone, and/or the like) performed by the electronic apparatus 1. The sound output module 1630 may include a receiver and a speaker. At least one of the receiver and the speaker may be a sound generator that is attached under the display panel 10 and vibrates the display panel 10 to output sounds. The sound generator may be a piezoelectric element or a piezoelectric actuator that contacts and expands according to electrical signals, or an exciter that generates magnetic force by using a voice coil to vibrate the display panel 10.

The camera module 1710 may capture still images and moving images. In one or more embodiments, the camera module 1710 may include at least one lens, an image sensor, and an image signal processor. The camera module 1710 may further include an infrared camera that may measure whether a user is present, a user's position, a user's gaze, and/or the like.

The light module 1720 may output signals for informing occurrence of an event using light of a light source, or provide light to obtain images. Here, examples of event occurrence include message reception, call signal reception, a missed call, an alarm, a calendar reminder, receiving an email, being notified of battery charge information, and/or the like. The light module 1720 may include a light-emitting diode and/or a xenon lamp. The light module 1720 may emit light of a single color or multiple colors to the front or back of the electronic apparatus 1. The light module 1720 may operate in cooperation with the camera module 1710 or independently.

The communication module 1730 may establish a wired or wireless communication channel between the electronic apparatus 1 and the external electronic apparatus 2000, and perform communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may transmit and receive wireless signals on the Internet using a wireless LAN) (WLAN), wireless-fidelity/Wi-Fi® (Wi-Fi® being a registered trademark of the non-profit Wi-Fi Alliance), Wi-Fi Direct™ (Wi-Fi Direct™ being a registered trademark of the non-profit Wi-Fi Alliance), and/or digital living network alliance (DLNA) technologies. In addition, the communication module 1730 may support short-range communication using Bluetooth® (Bluetooth® being a registered trademark of Bluetooth Sig, Inc., Kirkland, WA), radio frequency identification (RFID), infrared data association (IrDA), ultra wideband (UWB), Zigbee® (ZigBee® being a registered trademark of Connectivity Standards Alliance, CA), NFC, Wi-Fi®, Wi-Fi Direct™, and/or wireless USB technologies. The above-described various kinds of communication modules 1730 may be implemented in one chip or respectively implemented as separate chips.

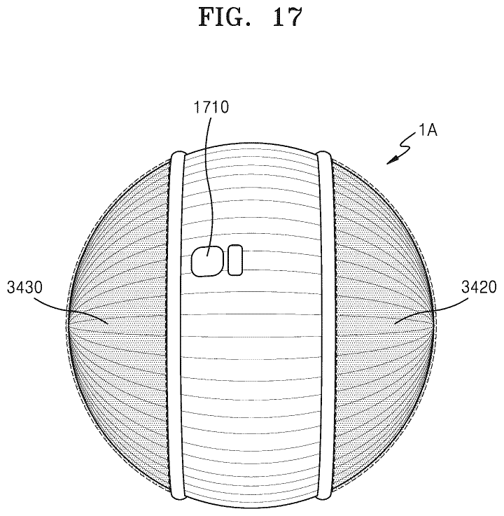

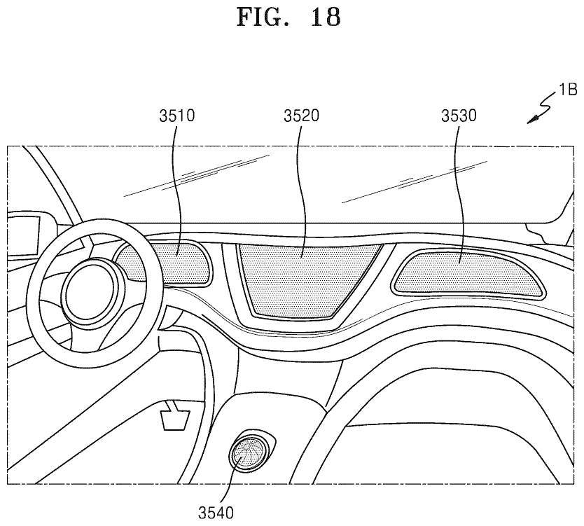

Although, in the embodiment described with reference to FIG. 15, it is described that the display panel 10 is freely transformed three-dimensionally and included in the electronic apparatus 1 providing an image surface that may be transformed three-dimensionally, the present disclosure is not limited thereto. As shown in FIGS. 17 and 18, the electronic apparatus may include an image providing region having a fixed shape, and the display panel may be disposed in the image providing region of the electronic apparatus during the process of manufacturing the electronic apparatus. The display panel in a three-dimensionally transformed state may be fixed to the electronic apparatus.

FIGS. 17 and 18 are perspective views of an electronic apparatus 1A and 1B according to one or more embodiments.

FIG. 17 shows a robot as the electronic apparatus 1A according to one or more embodiments. The robot may recognize a movement or object using a camera module 1710 and express preset images to a user through display portions 3420 and 3430. In one or more embodiments, because the display panels according to one or more embodiments may be stretched in various directions as described above, the display panels may be assembled to a frame of an electronic apparatus while the display panels are stretched three-dimensionally along the body frame having a hemispherical shape and may form display units 3420 and 3430.

FIG. 18 shows a vehicle display apparatus as an electronic apparatus 1B according to one or more embodiments. The vehicle display apparatus may include a cluster 3510, a center information display (CID) 3520, and/or a passenger display 3530. Because the display apparatus according to one or more embodiments may be stretched in various directions, the display apparatus may be used in the cluster 3510, the CID 3520, and/or the passenger display 3530 without being restricted by the shape of an internal frame of the vehicle.

Although it is shown in FIG. 18 that the cluster 3510, the CID 3520, and/or the passenger display 3530 are separated from each other, the present disclosure is not limited thereto. In another embodiment, two or more selected from the cluster 3510, the CID 3520, and the passenger display 3530 may be integrally connected.

In another embodiment, the vehicle display apparatus may include a button 3540 that may express preset images. The hemispherical button 3540 may sense a touch input in a z-direction or −z direction user (e.g., a driver).

Although it is shown in FIGS. 17 and 18 that the electronic apparatuses 1A and 1B are used in a robot or vehicle, the present disclosure is not limited thereto. The electronic apparatus according to the present disclosure may include electronic apparatuses for various purposes, such as commercial electronic apparatuses, office electronic apparatuses, educational electronic apparatuses, wearable electronic apparatuses, medical electronic apparatuses, and/or the like. In other words, as far as the display panel according to one or more embodiments includes a region that may display images, the display panel may be provided to various electronic apparatuses.

According to one or more embodiments, the high-quality display panel and electronic apparatus may be provided. The above effects, aspects, and features are just examples and are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display panel comprising:
a base layer including a first surface and a second surface opposite the first surface;
a first pixel circuit layer on the first surface of the base layer and comprising a transistor and insulating layers;
a second pixel circuit layer on the first surface of the base layer, spaced from the first pixel circuit layer, and comprising transistors and insulating layers;
a first light-emitting diode on the first pixel circuit layer and electrically connected to the transistor of the first pixel circuit layer;
a second light-emitting diode on the second pixel circuit layer and electrically connected to the transistor of the second pixel circuit layer;
a first line electrically connected to the transistor of the first pixel circuit layer;
a second line electrically connected to the transistor of the second pixel circuit layer; and
a connection line electrically connecting the first line to the second line,
wherein a first portion of the first line extends toward the connection line, and at least a portion of the first portion is embedded within the connection line.

2. The display panel of claim 1, wherein a bottom surface and a lateral surface of the first portion of the first line are in direct contact with the connection line.

3. The display panel of claim 1, wherein the insulating layers of each of the first pixel circuit layer and the second pixel circuit layer comprise:
an inorganic insulating stack comprising inorganic insulating layers; and
a first organic insulating layer on the inorganic insulating stack, and
wherein the first organic insulating layer of the first pixel circuit layer overlaps the first portion of the first line.

4. The display panel of claim 3, wherein the first organic insulating layer is in direct contact with an upper surface of the first portion of the first line.

5. The display panel of claim 3, wherein a portion of the base layer is in direct contact with a portion of a lateral surface of the inorganic insulating stack.

6. The display panel of claim 3, wherein the connection line comprises:
a first portion overlapping the first organic insulating layer and not overlapping the first portion of the first line; and
a second portion located between the first organic insulating layer of the first pixel circuit layer and the first organic insulating layer of the second pixel circuit layer, and
wherein a first thickness of the first portion of the connection line is greater than a second thickness of the second portion of the connection line.

7. The display panel of claim 6, wherein the connection line further comprises a third portion overlapping the first portion of the first line, and a third thickness of the third portion of the connection line is less than the first thickness.

8. The display panel of claim 3, wherein the insulating layers of each of the first pixel circuit layer and the second pixel circuit layer further comprise:
a second organic insulating layer on the first organic insulating layer; and
a third organic insulating layer located between the inorganic insulating stack and the first organic insulating layer and overlapping a lateral surface of the inorganic insulating stack, and
wherein a portion of the first line is between the third organic insulating layer and the first organic insulating layer.

9. The display panel of claim 3, wherein a width of the first organic insulating layer is greater than a width of the inorganic insulating stack.

10. The display panel of claim 1, wherein the first line comprises:
a first layer comprising a first metal; and
a second layer comprising a metal different from the first layer and located on the first layer,
wherein the second layer comprising a tip protruding in a lateral direction from a point at which a lateral surface of the first layer meets a bottom surface of the second layer, and
wherein the connection line is in direct contact with a lateral surface and a bottom surface of the tip.

11. The display panel of claim 1, further comprising a protective layer on the first light-emitting diode and the second light-emitting diode, wherein the protective layer is in direct contact with the connection line.

12. A display panel comprising:
a base layer including two first regions spaced from each other and a second region between the two first regions;
a first pixel circuit layer in one of the two first regions of the base layer and comprising a transistor and insulating layers;
a second pixel circuit layer in an other one of the two first regions of the base layer, spaced from the first pixel circuit layer, and comprising transistors and insulating layers;
a first light-emitting diode on the first pixel circuit layer and electrically connected to the transistor of the first pixel circuit layer;
a second light-emitting diode on the second pixel circuit layer and electrically connected to the transistor of the second pixel circuit layer;
a first line electrically connected to the transistor of the first pixel circuit layer;
a second line electrically connected to the transistor of the second pixel circuit layer; and
a connection line electrically connecting the first line to the second line,
wherein the first line extends toward the connection line, and a bottom surface and a lateral surface of a first portion of the first line are in direct contact with the connection line.

13. The display panel of claim 12, wherein the insulating layers of each of the first pixel circuit layer and the second pixel circuit layer comprise:
an inorganic insulating stack comprising inorganic insulating layers; and
a first organic insulating layer on the inorganic insulating stack, and
wherein the first organic insulating layer overlaps the first portion of the first line.

14. The display panel of claim 13, wherein the connection line comprises:
a first portion overlapping the first organic insulating layer and not overlapping the first portion of the first line; and
a second portion located in the second region, and
wherein a first thickness of the first portion of the connection line is greater than a second thickness of the second portion of the connection line.

15. The display panel of claim 14, wherein the connection line further comprises a third portion overlapping the first portion of the first line, and a third thickness of the third portion of the connection line is less than the first thickness.

16. The display panel of claim 13, wherein the insulating layers of each of the first pixel circuit layer and the second pixel circuit layer further comprise a second organic insulating layer between the inorganic insulating stack and the first organic insulating layer and overlapping a lateral surface of the inorganic insulating stack, and
wherein a portion of the first line is between the second organic insulating layer and the first organic insulating layer.

17. The display panel of claim 13, wherein a portion of the base layer is in direct contact with a portion of a lateral surface of the inorganic insulating stack.

18. The display panel of claim 13, wherein the first organic insulating layer is in direct contact with an upper surface of the first portion of the first line, and
wherein the display panel further comprises a protective layer on the first light-emitting diode and the second light-emitting diode, wherein the protective layer is in direct contact with the connection line.

19. The display panel of claim 12, wherein the first line comprises:
a first layer comprising a first metal; and
a second layer comprising a metal different from the first layer and located on the first layer, wherein the second layer comprises a tip protruding in a lateral direction from a point at which a lateral surface of the first layer meets a bottom surface of the second layer, and
wherein the connection line is in direct contact with a lateral surface and a bottom surface of the tip.

20. An electronic device comprising a display panel, the display panel comprising:
a base layer including a first surface and a second surface opposite the first surface;
a first pixel circuit layer on the first surface of the base layer and comprising a transistor and insulating layers;
a second pixel circuit layer on the first surface of the base layer, spaced from the first pixel circuit layer, and comprising transistors and insulating layers;
a first light-emitting diode on the first pixel circuit layer and electrically connected to the transistor of the first pixel circuit layer;
a second light-emitting diode on the second pixel circuit layer and electrically connected to the transistor of the second pixel circuit layer;
a first line electrically connected to the transistor of the first pixel circuit layer;
a second line electrically connected to the transistor of the second pixel circuit layer; and
a connection line electrically connecting the first line to the second line,
wherein a first portion of the first line extends toward the connection line, and at least a portion of the first portion is embedded within the connection line.
